(19) United States
(12) Patent Application Publication
(10) Pub. No.: US 2025/0151260 A1
(43) Pub. Date: May 8, 2025

(54) SEMICONDUCTOR DEVICES

(71) Applicant: SAMSUNG ELECTRONICS CO., LTD., Suwon-si (KR)

(72) Inventors: Taehyuk Kim, Suwon-si (KR); Taejin Park, Suwon-si (KR); Hyeran Lee, Suwon-si (KR); Sungsoo Yim, Suwon-si (KR)

(21) Appl. No.: 18/739,698

(22) Filed: Jun. 11, 2024

(30) Foreign Application Priority Data
Nov. 8, 2023 (KR) 10-2023-0153399

(51) Int. Cl. H10B 12/00; H01L 29/78

(52) U.S. Cl. CPC H10B 12/482; H10B 12/0335; H10B 12/315; H10D 30/63

(57) ABSTRACT

A semiconductor device includes bit line structures spaced apart from each other in a first direction, and each of the bit line structures extends in a second direction; channels on the bit line structures, wherein the channels are electrically connected to the bit line structures and spaced apart from each other in the first direction; a gate insulation pattern structure on sidewalls of each of the channels; a gate electrode structure including: a first gate electrode on a first sidewall of the gate insulation pattern structure; and a second gate electrode on a second sidewall of the gate insulation pattern structure, wherein the second sidewall faces the first sidewall in the second direction, wherein the second gate electrode is on a third sidewall in the first direction of an end portion of the gate insulation pattern structure, and wherein the second gate electrode contacts the first gate electrode.

### CROSS-REFERENCE TO RELATED APPLICATIONS

This application claims priority under 35 U.S.C. § 119 to Korean Patent Application No. 10-2023-0153399 filed on Nov. 8, 2023 in the Korean Intellectual Property Office, the disclosure of which is hereby incorporated by reference in its entirety.

### TECHNICAL FIELD

Example embodiments of the present inventive concepts relate to semiconductor devices. More particularly, example embodiments relate to semiconductor devices including a vertical channel.

### DESCRIPTION OF RELATED ART

Memory devices including vertical channel transistors are being developed to improve integration of semiconductor devices. The vertical channel transistor may include a vertical channel and a gate structure, and the vertical channel may have a Gate All Around (GAA) structure where the gate structure extends arounds (e.g., surrounds) four sides of the vertical channel. As the aspect ratio of the vertical channel increases, the vertical channel may bend or collapse.

### SUMMARY OF THE INVENTION

Example embodiments of the present inventive concepts provide a semiconductor having improved characteristics.

According to example embodiments, there is provided a semiconductor device. The semiconductor device may include a substrate; bit line structures on the substrate, wherein the bit line structures are spaced apart from each other in a first direction that is parallel with an upper surface of the substrate, and each of the bit line structures extends in a second direction that is parallel with the upper surface of the substrate and intersects the first direction; channels on the bit line structures, wherein the channels are electrically connected to the bit line structures and spaced apart from each other in the first direction; a gate insulation pattern structure on sidewalls of each of the channels; a gate electrode structure including: a first gate electrode on a first sidewall in the second direction of the gate insulation pattern structure; and a second gate electrode on a second sidewall in the second direction of the gate insulation pattern structure, wherein the second sidewall of the gate insulation pattern structure faces the first sidewall of the gate insulation pattern structure in the second direction, wherein the second gate electrode is on a third sidewall in the first direction of an end portion in the first direction of the gate insulation pattern structure, and wherein the second gate electrode is in contact with the first gate electrode; and capacitors on the channels, wherein the capacitors are electrically connected to the channels, respectively.

According to example embodiments, there is provided a semiconductor device. The semiconductor device may include a substrate; bit line structures on the substrate, wherein the bit line structures are spaced apart from each other in a first direction that is parallel with an upper surface of the substrate, and each of the bit line structures extends in a second direction that is parallel with the upper surface of the substrate and intersects the first direction; an insulation pattern structure on the bit line structures, wherein the insulation pattern structure extends in the first direction; a gate isolation pattern that is in contact with an end portion in the first direction of the insulation pattern structure; channels on the bit line structures, wherein the channels are electrically connected to the bit line structures and spaced apart from each other in the first direction on opposite sidewalls in the second direction of the insulation pattern structure; a gate insulation pattern structure on the bit line structures, wherein the gate insulation pattern structure is on the opposite sidewalls in the second direction of the insulation pattern structure and sidewalls of the channels; a gate electrode structure on the bit line structures, wherein the gate electrode structure is on the opposite sidewalls in the second direction of the insulation pattern structure, wherein the gate electrode structure at least partially extends around the gate insulation pattern structure, and wherein the gate electrode structure overlaps in the second direction with the gate isolation pattern; and capacitors on the channels, wherein the capacitors are electrically connected to the channels, respectively.

According to example embodiments, there is provided a semiconductor device. The semiconductor device may include a substrate; bit line structures on the substrate, wherein the bit line structures are spaced apart from each other in a first direction that is parallel with an upper surface of the substrate, and each of the bit line structures extends in a second direction that is parallel with the upper surface of the substrate and intersects the first direction; an insulation pattern structure on the bit line structures, wherein the insulation pattern structure extends in the first direction; channels on the bit line structures, wherein the channels are electrically connected to the bit line structures and spaced apart from each other in the first direction on opposite sidewalls in the second direction of the insulation pattern structure; a gate isolation pattern that is in contact with an end portion in the first direction of the insulation pattern structure; a gate insulation pattern structure on sidewalls of each of the channels; a gate electrode structure including: a first gate electrode on a first sidewall in the second direction of the gate insulation pattern structure; and a second gate electrode on a second sidewall in the second direction of the gate insulation pattern structure, wherein the second sidewall of the gate insulation pattern structure faces the first sidewall of the gate insulation pattern structure in the second direction, wherein the second gate electrode is on a third sidewall in the first direction of an end portion in the first direction of the gate insulation pattern structure, and wherein the second gate electrode is in contact with the first gate electrode; capacitors on the channels, wherein the capacitors are electrically connected to the channels; and contact plug that is in contact with the second gate electrode.

In a method of manufacturing a semiconductor device including a vertical channel transistor according to example embodiments, a portion of a gate structure is first formed, a channel is formed, and after, a remaining portion of the gate structure is formed. Thus, the channel surrounded by the gate structure may be prevented from bending or collapsing.

Additionally, first and second gate insulation patterns included in a gate insulation pattern structure may be formed by separate processes and first and second gate electrodes included in a gate electrode structure may be also formed by separate processes. Therefore, electrical characteristics such as threshold voltage of the vertical channel transistor may be easily adjusted.

### BRIEF DESCRIPTION OF THE DRAWINGS

FIGS. 1 to 3 are a plan view and cross-sectional views illustrating a semiconductor device in accordance with example embodiments.

FIGS. 4 to 44 are plan views and cross-sectional views illustrating a method of manufacturing a semiconductor device according to example embodiments.

FIGS. 45 to 47 are a plan view and cross-sectional views illustrating a semiconductor device in accordance with example embodiments.

FIGS. 48 to 58 are plan views and cross-sectional views illustrating a method of manufacturing a semiconductor device according to example embodiments.

### DETAILED DESCRIPTION

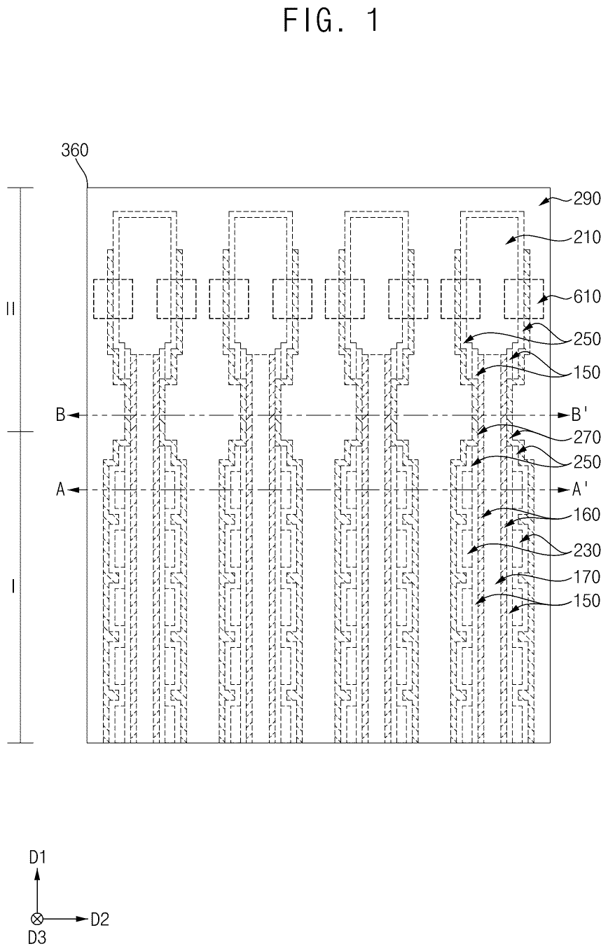

Hereinafter, two directions among horizontal directions that are (substantially) parallel to an upper surface of an insulating interlayer (e.g., the third insulating interlayer 600 in FIG. 1), which may cross each other, may be referred as first and second directions D1 and D2, respectively. Additionally, a direction (substantially) perpendicular to the upper surface of the insulating interlayer may be referred to as a third direction D3. The insulating interlayer (e.g., the third insulating interlayer 600) may be referred to as a substrate to describe directions such as the first, second, and third directions D1, D2, and D3. In example embodiments, the first and second directions D1 and D2 may intersect each other. For example, the first and second directions D1 and D2 may be (substantially) orthogonal to each other. Meanwhile, each of the first, second, and third directions D1, D2 and D3 may mean not only the direction shown in the figures, but also the direction opposite thereto.

The above and other aspects and features of the semiconductor devices and the methods of manufacturing the same in accordance with example embodiments of the present inventive concepts will be more fully described from detail descriptions that follow, with reference to the accompanying drawings. It will be understood that, although the terms “first,” “second,” and/or “third” may be used herein to describe various materials, layers, regions, pads, electrodes, patterns, structure, and/or processes, these various materials, layers, regions, pads, electrodes, patterns, structure, and/or processes should not be limited by these terms. These terms are only used to distinguish one material, layer, region, pad, electrode, pattern, structure, or process from another material, layer, region, pad, electrode, pattern, structure, or process. Thus, “first”, “second,” and/or “third” may be used selectively or interchangeably for each material, layer, region, electrode, pad, pattern, structure, or process respectively. As used herein, the term “and/or” includes any and all combinations of one or more of the associated listed items. Expressions such as “at least one of,” when preceding a list of elements, modify the entire list of elements and do not modify the individual elements of the list.

FIG. 1 is a plan view illustrating a semiconductor device in accordance with example

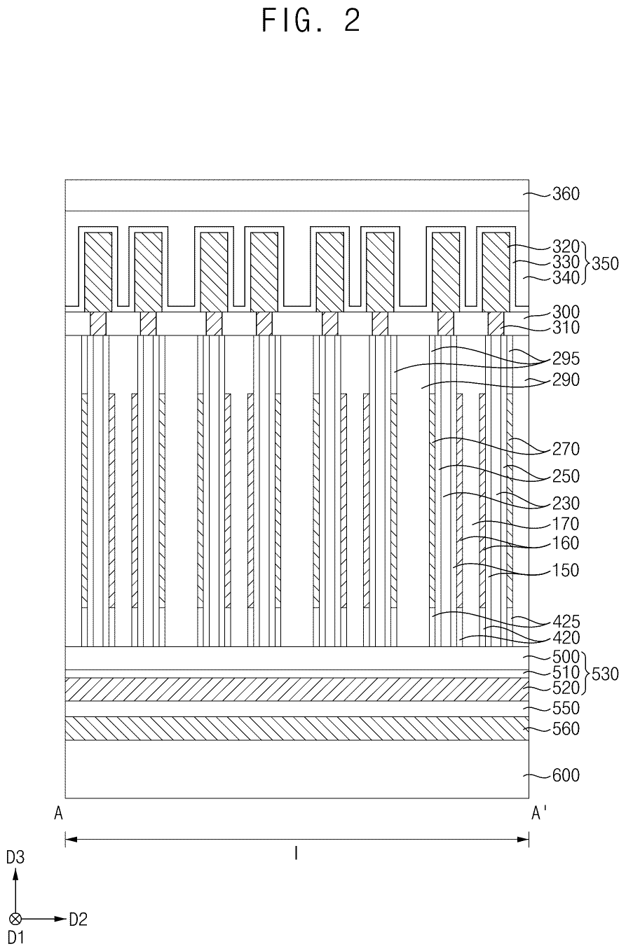

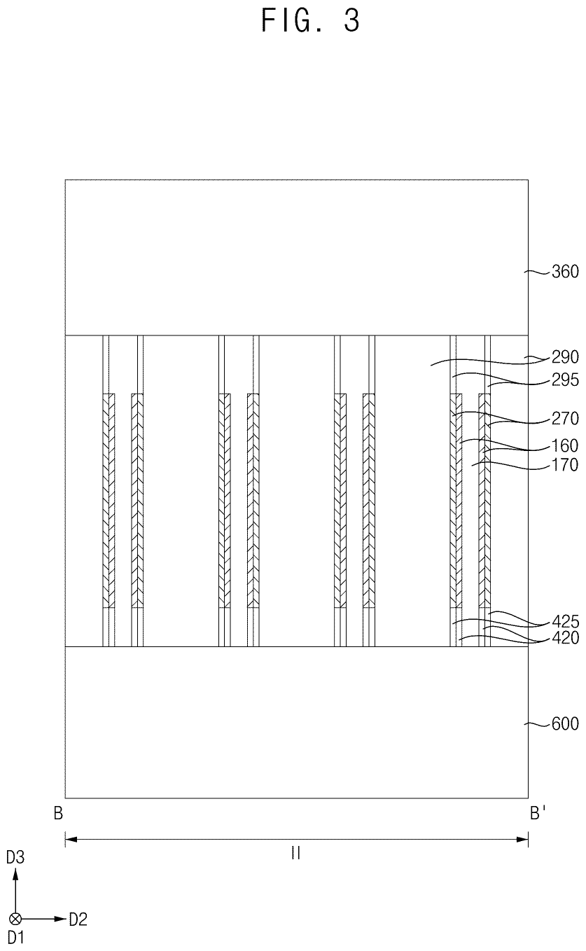

embodiments, FIG. 2 is a cross-sectional view taken along line A-A′ of FIG. 1, and FIG. 3 is a cross-sectional view taken along line B-B′ of FIG. 1.

Referring to FIGS. 1 to 3, the semiconductor device may include a bit line structure 530, a bit line shield structure 560, a channel 230, a first gate structure, a landing pad 310 and a capacitor 350.

The semiconductor device may further include first, second, and third insulating interlayers 300, 360, and 600, a gate isolation pattern 210, a contact plug 610, first and second insulation pattern structures, and a sixth insulation pattern 550.

The semiconductor device may include a first region I and a second region II. In example embodiments, the first region I may be a cell array region where memory cells may be formed and the second region II may be a peripheral circuit region where a peripheral circuit pattern may apply electrical signals for operating the memory cells.

In FIG. 1, the first and second regions I and II are arranged in the first direction D1, but the concept of the present invention is not limited thereto. For example, the first and second regions I and II may be arranged in the second direction D2. For example, the second region II may extend around (e.g., surround) the first region I. For example, the second region II may be formed on opposite sides in the first direction D1 or in the second direction D2 of the first region I.

In an example embodiment, the semiconductor device may have a Cell Over Periphery (COP) structure in which at least a portion of a peripheral circuit pattern may be formed below the memory cells. In another example embodiment, the semiconductor device may have a Periphery Over Cell (POC) structure in which at least a portion of the peripheral circuit pattern may be formed above the memory cells. Spatially relative terms, such as “beneath,” “below,” “lower,” “above,” “upper,” “higher” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is turned over, elements described as “below” or “beneath” other elements or features would then be oriented “above” the other elements or features. Thus, the term “below” can encompass both an orientation of above and below. The device may be otherwise oriented (e.g., rotated 90 degrees or at other orientations) and the spatially relative descriptors used herein may be interpreted accordingly.

The peripheral circuit pattern may include, for example, transistors, contact plugs, wires, vias, etc. The peripheral circuit pattern may include, for example, a bit line sense amplifier (BLSA), sub-word line driver (SWD), column decoder, column selection line (CSL) driver, input/output sense amplifier (I/O SA), write driver, etc.

The third insulating interlayer 600 may include, for example, an oxide such as silicon oxide or a low dielectric material.

The bit line shield structure 560 may be formed on a portion of the third insulating interlayer 600 on the first region I.

In example embodiments, the bit line shield structure 560 may include a bit line shield plate and a bit line shield fin that may be stacked in the third direction D3 and contact each other. In example embodiments, the bit line shield plate may have a flat shape (substantially) parallel to an upper surface of the third insulating interlayer 600. The bit line shield fins may protrude from the bit line shield plate in the third direction D3 and extend in the second direction D2. The bit line shield fin may be one of a plurality of bit line shield fins spaced apart from each other in the first direction D1.

The bit line shield structure 560 may include for example, a conductive material such as a metal, a metal nitride, or a metal silicide.

The sixth insulation pattern 550 may be on (e.g., cover or overlap in the third direction D3) an upper surface of the bit line shield structure 560. The sixth insulation pattern 550 may include, for example, an oxide such as silicon oxide. As used herein, “an element A overlapping an element B in a direction X” (or similar language) means that there is at least one line that extends in the direction X and intersects both the elements A and B.

The bit line structure 530 may be formed on the sixth insulation pattern 550 on the first region I and extend in the second direction D2. The bit line structure 530 may be one of a plurality of bit line structures spaced apart from each other in the first direction D1. Each of the bit line structures 530 may be formed between the bit line shield fins adjacent to each other in the first direction D1. The sixth insulation pattern 550 may be on (e.g., may cover) a lower surface and/or a sidewall of the bit line structure 530.

In example embodiments, the bit line structure 530 may include a second conductive pattern 520, a barrier pattern 510, and a first conductive pattern 500 sequentially stacked in the third direction D3. The second conductive pattern 520 may include, for example, a metal and/or a metal nitride, the barrier pattern 510 may include, for example, a metal silicon nitride such as titanium silicon nitride, and the first conductive pattern 500 may include, for example, polysilicon doped with impurities.

In some embodiments, the bit line structure 530 may include a conductive pattern having a metal and/or a metal nitride, and a barrier pattern having a metal silicon nitride.

The gate isolation pattern 210 may be formed on the third insulating interlayer 600 in the second region II. The gate isolation pattern 210 may be one of a plurality of gate isolation patterns spaced apart from each other along in the second direction D2. The gate isolation pattern 210 may include, for example, an oxide such as silicon oxide or a nitride such as silicon nitride.

In example embodiments, the gate isolation pattern 210 may include a bulk portion and a protruding structure protruding from the bulk portion towards the first region I. In a plan view, the bulk portion may have a rectangular shape in which a length in the first direction D1 may be longer than a length in the second direction D2, but the shape of the bulk portion of the gate isolation pattern 210 in a plan view is not limited thereto. The protruding structure may include a first protruding portion and a second protruding portion sequentially disposed in the first direction D1 at one side in the first direction D1 of the bulk portion of the gate isolation pattern 210 that is close to the first region I. For example, in a plan view, the first protruding portion may be farther than the second protruding portion from the first region I in the first direction D1. For example, in a plan view, the first protruding portion may be closer than the second protruding portion to the bulk portion in the first direction D1.

A width in the second direction D2 of the first protruding portion may be smaller than a width in the second direction D2 of the bulk portion, and a width in the second direction D2 of the second protruding portion may be smaller than the width in the second direction D2 of the first protruding portion. Accordingly, in a plan view, the first and second protruding portions may be arranged in steps from the bulk portion along the first direction D1. For example, the first protruding portion, the second protruding portion, and the bulk portion may form a stair shape going up in the first direction D1 (and/or the second direction D2). In some embodiments, the first protruding portion, the second protruding portion, and the bulk portion may form a unitary structure. A unitary structure herein may refer to a structure without a visible boundary between two sub-elements thereof.

The first insulation pattern structure may extend in the first direction D1 from one side in the first direction D1 of each of the second protruding portions. Accordingly, the first insulation pattern structure may be one of a plurality of first insulation pattern structures that may be spaced apart from each other in the second direction D2. In example embodiments, a maximum width in the second direction D2 of the first insulation pattern structure may be (substantially) equal to the width in the second direction D2 of the second protruding portion of the gate isolation pattern 210.

In example embodiments, the first insulation pattern structure may include a first insulation pattern 170 extending in the first direction D1 and a fourth insulation pattern 420 extending in the first direction D1 along a lower portion of opposite sidewalls in the second direction D2 of the first insulation pattern 170. For example, the fourth insulation pattern 420 may be on a portion of the opposite sidewalls in the second direction D2 of the lower portion of the first insulation pattern 170. Each of the first and fourth insulation patterns 170 and 420 may include, for example, an insulating material. That is, each of the first and fourth insulation patterns 170 and 420 may include, for example, an oxide such as silicon oxide, a nitride such as silicon nitride, or air (e.g., gas or a space). As described later, the first and fourth insulation patterns 170 and 420 may be formed by separate processes. Hence, the first and fourth insulation patterns 170 and 420 may include different materials, or may include the same materials and be merged with each other. For example, the first and fourth insulation patterns 170 and 420 may form a unitary structure.

In example embodiments, the first insulation pattern 170 may include a lower portion and an upper portion sequentially stacked in the third direction D3. A width in the second direction D2 of the lower portion of the first insulation pattern 170 may be smaller than a width in the second direction D2 of the upper portion of the first insulation pattern 170.

The channel 230 and the first gate structure may together form a transistor.

The channel 230 may be one of a plurality of channels 230 that may be formed on the bit line structure 530 and the sixth insulation pattern 550 and spaced apart from each other in the first direction D1. In example embodiments, the channels 230 may contact an upper surface of the first conductive pattern 500 of the bit line structure 530 extending in the second direction D2 to be spaced apart from each other in the second direction D2. For example, the plurality of channels 230 may be spaced apart from each other in the first direction D1 and/or the second direction D2.

The channel 230 may include, for example, a semiconductor material such as silicon, germanium, silicon-germanium, or an oxide semiconductor material such as IGZO.

In example embodiments, the first gate structure may be formed on the bit line structure 530 and the sixth insulation pattern 550 to extend in the first direction D1 along opposite sidewalls in the second direction D2 of the gate isolation pattern 210 and the first insulation pattern structure corresponding thereto. Accordingly, the first gate structure may be one of a plurality of first gate structures spaced apart from each other in the second direction D2.

The first gate structure may include a gate insulation pattern structure including the first and second gate insulation patterns 150 and 250, and a gate electrode structure including the first and second gate electrodes 160 and 270.

Each of the first and second gate insulation patterns 150 and 250 may extend in the first direction D1 on the third insulating interlayer 600, the bit line structure 530, and the sixth insulation pattern 550. In example embodiments, the gate insulation pattern structure may be separated from each other in the first direction D1 near the boundary of the first and second regions I and II. For example, in a plan view, the first gate insulation patterns 150 may be spaced apart from each other in the first direction D1 near (adjacent) the boundary of the first and second regions I and II, and, in a plan view, the second gate insulation patterns 250 may be spaced apart from each other in the first direction D1 near (adjacent) the boundary of the first and second regions I and II.

In example embodiments, in a plan view, the first gate insulation pattern 150 may extend in the first direction D1 in a straight line on each of the first and second regions I and II. However, a length in the first direction D1 of a portion of the first gate insulation pattern 150 formed in the second region II may be shorter than a length in the first direction D1 of a portion of the first gate insulation pattern 150 formed in the first region I. The first gate insulation pattern 150 in the first region I may overlap the first gate insulation pattern 150 in the second region II in the first direction D1. For example, the portion of the first gate insulation pattern 150 formed in the second region II may be aligned with the portion of the first gate insulation pattern 150 formed in the first region I in the first direction D1.

In a plan view, a portion of the second gate insulation pattern 250 in the second region II may be formed along a sidewall of the gate isolation pattern 210, and a portion of the second gate insulation pattern 250 in the first region I may extend in the first direction D1 while bending in the second direction D2. A second sidewall of the second gate insulation pattern 250 may contact a portion of a first sidewall (e.g., an outer sidewall) of the first gate insulation pattern 150 facing the second sidewall of the second gate insulation pattern 250.

In example embodiments, the first gate insulation pattern 150 may contact a first sidewall in the second direction D2 of the channel 230, and the second gate insulation pattern 250 may contact a second sidewall in the second direction D2 of the channel 230 facing the first sidewall of the channel 230 and opposite sidewalls in the first direction D1 of the channel 230. For example, the first sidewall of the first gate insulation pattern 150 may be in contact with the first sidewall of the channel 230. Accordingly, in a plan view, the gate insulation pattern structure including the first and second gate insulation patterns 150 and 250 may extend around (e.g., surround) the sidewalls of each channel 230 in the first region I. For example, in a plan view, the first gate insulation pattern 150 may be on one sidewall (e.g., one of opposite sidewalls in the second direction D2, which may be referred to as the first sidewall) of the channel 230, and the second gate insulation pattern 250 may be on three sidewalls (e.g., the other of opposite sidewalls in the second direction D2, which may be referred to as the second sidewall and opposite sidewalls in the first direction D1) of the channel 230.

Each of the first and second gate insulation patterns 150 and 250 may include, for example, an oxide such as silicon oxide, or a nitride such as silicon nitride. The first and second gate insulation patterns 150 and 250 may be formed by separate processes, and therefore may include different materials and/or have different thicknesses.

The first gate electrode 160 may be disposed on the fourth insulation pattern 420 and extend in the first direction D1 along a second sidewall in the second direction D2 of the first gate insulation pattern 150 facing the first sidewall of the first gate insulation pattern 150. The second gate electrode 270 may be disposed on the fifth insulation pattern 425 and extend in the first direction D1 along a first sidewall in the second direction D2 of the second gate insulation pattern 250 facing the second sidewall of the second gate insulation pattern 250, and a sidewall in the second direction D2 of the gate isolation pattern 210 corresponding thereto (e.g., the gate isolation pattern 210 that overlaps the second gate insulation pattern 250 in the first direction D1).

In a plan view, the first gate electrode 160 may extend in the first direction D1 in a straight line on the first region I and the second region II adjacent thereto.

The second gate electrode 270 may include an extension portion extending in the first direction D1 in a straight line on the first region I and a plurality of protruding portions protruding from the extension portion in the second direction, respectively, and spaced apart from each other in the first direction D1 in a plan view. For example, in a plan view, the protruding portions may be spaced apart from each other in the first direction D1 by the second gate insulation pattern 250.

In example embodiments, the first gate electrode 160 may directly contact one side in the first direction D1 of the second protruding portion of the gate isolation pattern 210.

The first and second gate electrodes 160 and 270 may contact (e.g., directly contact) each other in a boundary region of the first and second regions I and II where the gate insulation pattern structures are separated from each other. Accordingly, the first and second gate electrodes 160 and 270 may be electrically connected to each other. It will be understood that when an element or layer is referred to as being “connected to”, “coupled to”, or “in contact with” another element or layer, it may be directly on, connected to, coupled to, or in contact with the other element or layer, or one or more intervening elements or layers may be present. In contrast, when an element is referred to as being “directly coupled,” “directly connected,” or “directly responsive” to, “directly on,” or “in direct contact with” another element, there are no intervening elements present. In addition, “electrical connection” conceptually includes a physical connection and a physical disconnection.

In the first region I, the gate electrode structure including the first and second gate electrodes 160 and 270 may cover (e.g., overlap in the second direction D2) sidewalls in the second direction D2 of the gate insulation pattern structure and may cover (e.g., overlap in the first direction D1) a sidewall in the first direction D1 of the gate insulation pattern structure adjacent to the second region II. In an example embodiment, the gate electrode structure may cover (e.g., overlap in the first direction D1) another sidewall in the first direction D1 of the gate insulation pattern structure in the first region I. Accordingly, the gate electrode structure may cover (e.g., overlap in the first direction D1 and the second direction D2) the sidewalls of the gate insulation pattern structure as a whole. For example, in a plan view, the gate electrode structure (including the first and second gate electrodes 160 and 270) may extend around (e.g., surround) the gate insulation pattern structure (including the first and second gate insulation patterns 150 and 250).

Each of the first and second gate electrodes 160 and 270 may include, for example, a metal, a metal nitride, a metal silicide, or polysilicon doped with impurities. The first and second gate electrodes 160 and 270 may include the same material or different materials. The first and second gate electrodes 160 and 270 may have the same thickness or different thicknesses. Each of the first and second gate electrodes 160 and 270 may serve as a word line.

In example embodiments, upper surfaces of the first and second gate electrodes 160 and 270 may be lower than an upper surface of the channel 230, and lower surfaces of the first and second gate electrodes 150 and 270 may be higher than a lower surface of the channel 230. The vertical level may be a relative location (e.g., distance) from an upper surface of the third insulating interlayer 600 in the vertical direction (e.g., the third direction D3). A farther distance from the upper surface of the third insulating interlayer 600 may be referred to as higher. A closer distance from the upper surface of the third insulating interlayer 600 may be referred to as lower.

Hereinafter, the gate isolation pattern 210, the first insulation pattern structure, the first gate structure, and the channel 230 may be together referred to as a first extension structure. In example embodiments, the first extension structure may be one of a plurality of first extension structures spaced apart from each other in the second direction D2.

The second insulation pattern structure may be formed on the third insulating interlayer 600, the bit line structure 530, and the sixth insulation pattern 550 to (at least partially) fill a space between the first extension structures. The second insulation pattern structure may include second, third and fifth insulation patterns 290, 295, and 425.

The second insulation pattern 290 may include a first extension portion extending in the second direction D2 on the second region II and a second extension portion extending in the first direction D1 between ones of the first extension structures adjacent to each other in the direction D2 on the first and second regions I and II. In example embodiments, the second extension portion may be one of a plurality of second extension portions spaced apart from each other in the second direction D2 by the first extension structures. For example, the first extension structures and the second extension portions of the second insulation pattern 290 may be alternately arranged in the second direction D2. Each of the second extension portions may be connected to the first extension portion to be integrally formed (e.g., to form a unitary structure).

The third insulation pattern 295 may extend in the first direction D1 and may be on (e.g., cover or overlap in the second direction D2) upper portions of opposite sidewalls in the second direction D2 of each of the second extension portions of the second insulation pattern 290. The fifth insulation pattern 425 may extend in the first direction D1 and may be on (e.g., cover or overlap in the second direction D2) lower portions of opposite sidewalls in the second direction D2 of each of the second extension portions of the second insulation pattern 290. For example, the third insulation pattern 295 and the fifth insulation pattern 425 may be in contact with the second extension portion of the second insulation pattern 290.

Each of the second, third, and fifth insulation patterns 290, 295, and 425 may include, for example, an oxide such as silicon oxide, a nitride such as silicon nitride, or air (e.g., gas or a space). The second, third, and fifth insulation patterns 290, 295, and 425 may be formed by separate processes. Thus, the second, third, and fifth insulation patterns 290, 295, and 425 may include different materials, or may include the same materials and be merged with each other. In some embodiments, the second insulation pattern structure including the second, third, and fifth insulation patterns 290, 295, and 425 may form a unitary structure.

The contact plug 610 may extend through the third insulating interlayer 600 and the fifth insulation pattern 425 to directly contact the second gate electrode 270. The second gate electrode 270 may be in direct contact with the first gate electrode 160, and thus, same voltage (e.g., same voltage value) may be applied to the first and second gate electrodes 160 and 270 (simultaneously).

In FIGS. 1 to 3, the contact plug 610 is formed on a back side of the semiconductor device to contact the first gate electrode 160, but the concept of the present invention is not limited thereto. That is, the contact plug 610 may be formed on a front side of the semiconductor device rather than on the back side of the semiconductor device. In some embodiments, the contact plug 610 may (extend through the fourth insulating pattern 420 and) contact the first gate electrode 160 rather than the second gate electrode 270. That is, the contact plug 610 may directly contact at least one of the first and second gate electrodes 160 and 270.

The first insulating interlayer 300 may be formed on the channel 230, the first and second gate insulation patterns 150 and 250, and the first, second, and third insulation patterns 170, 290, and 295. The first insulating interlayer 300 may include, for example, an oxide such as silicon oxide or a low dielectric material.

The landing pad 310 may extend through the first insulating interlayer 300 to contact an upper surface of the channel 230. The landing pad 310 may include, for example, a metal, a metal nitride, or a metal silicide.

The capacitor 350 may include a first capacitor electrode 320, a dielectric pattern 330, and a second capacitor electrode 340.

In example embodiments, the first capacitor electrode 320 may be one of a plurality of first capacitor electrodes 320 spaced apart from each other in the first and second directions D1 and D2 and may contact an upper surface of a corresponding one of the landing pad 310. The dielectric pattern 330 may be formed on upper surfaces and sidewalls of the first capacitor electrodes 320 and an upper surface of the first insulating interlayer 300. The second capacitor electrode 340 may be formed on the dielectric pattern 330.

The first capacitor electrode 320 may include, for example, a metal, a metal nitride, or a metal silicide, the dielectric pattern 330 may include, for example, a metal oxide, and the second capacitor electrode 340 may include, for example, a metal, a metal nitride, a metal silicide, a silicon-germanium doped with impurities, etc.

The second insulating interlayer 360 may be formed on the first insulating interlayer 300 to cover (e.g., overlap in the third direction D3) the capacitor 350. For example, the second insulating interlayer 360 may be on an upper surface of the second capacitor electrode 340. The second insulating interlayer 360 may include, for example, an oxide such as silicon oxide or a low dielectric material.

In the semiconductor device, electrical current may flow in the third direction D3, that is, a vertical direction, within the channel 230. Accordingly, the semiconductor device may include a vertical channel transistor (VCT) having a vertical channel. The vertical channel transistor may have a Gate-All-Around (GAA) structure since the first gate structure may extend around (e.g., surround in a plan view) the channel 230. For example, the first gate structure, including the first and second gate electrodes 160 and 270 and first and second gate insulation patterns 150 and 250, may extend around (e.g., surround) the sidewalls of the channel 230.

In the semiconductor device, the first and second gate electrodes 160 and 270 may be in direct contact to each other. Thus, even if the contact plug 610 is only connected (e.g., only in contact with) one of the first and second gate electrodes 160 and 270, same voltage (e.g., same voltage value) may be applied (simultaneously) to the first and second gate electrodes 160 and 270 by the contact plug 610.

Additionally, the first and second gate insulation patterns 150 and 250 may have different materials and/or thicknesses, and the first and second gate electrodes 160 and 270 may also have different materials and/or thicknesses. Accordingly, compared to a transistor including a gate structure having one gate insulation pattern and one gate electrode, characteristics, such as threshold voltage, of the transistor including the first gate structure according to example embodiments may be easily adjusted. That is, the transistor may have desired electrical characteristics by adjusting the material and/or thickness of the first and second gate insulation patterns 150 and 250 and the first and second gate electrodes 160 and 270 of the first gate structure.

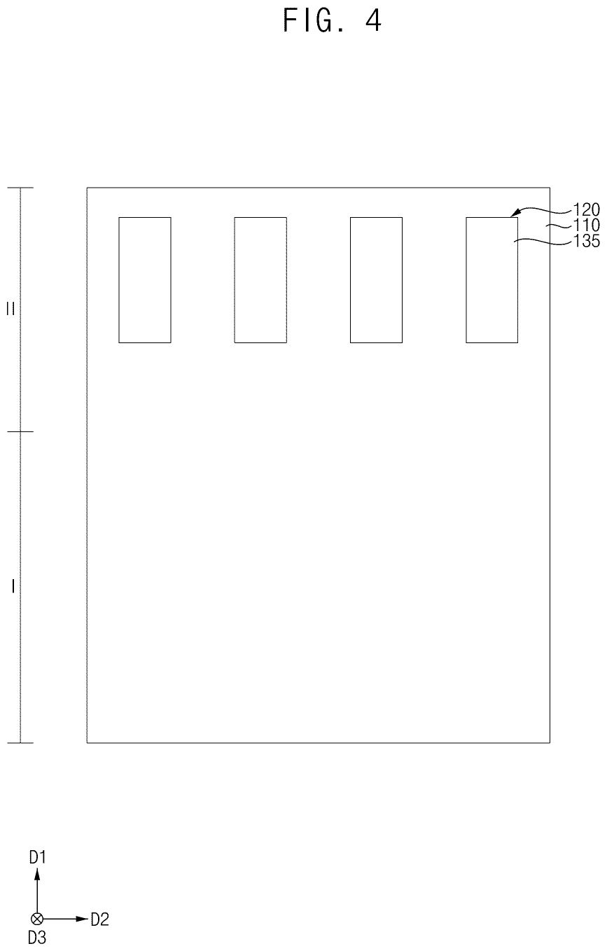

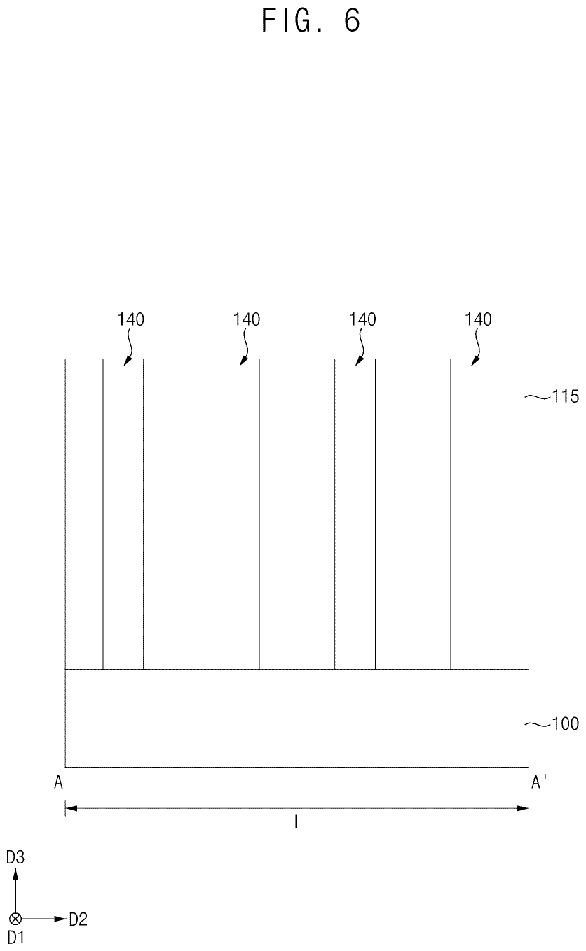

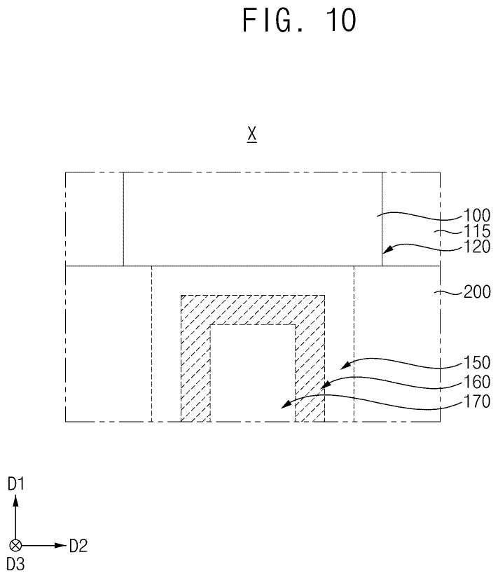

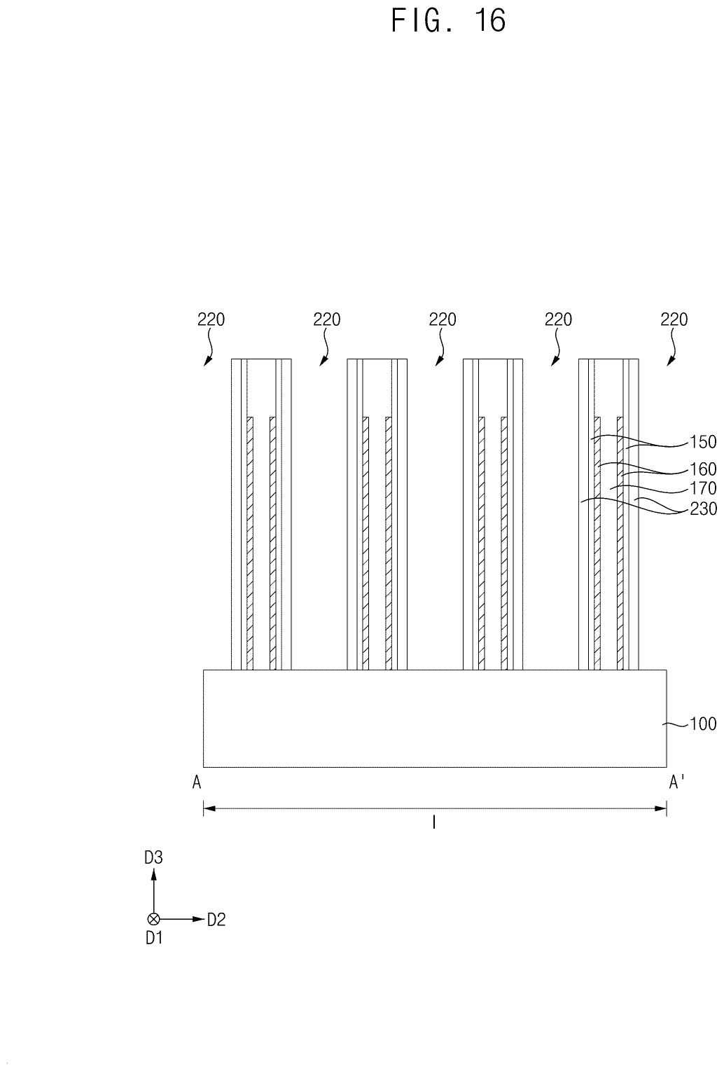

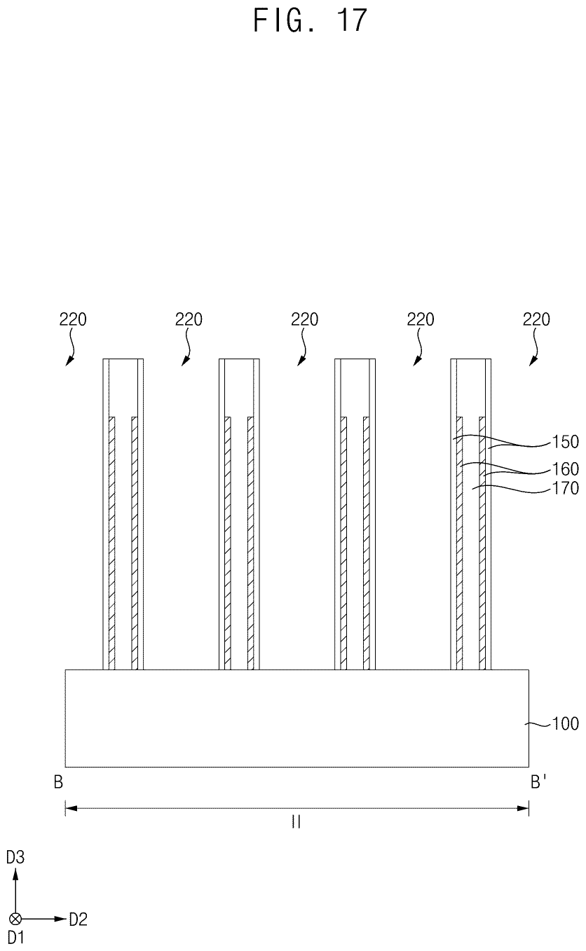

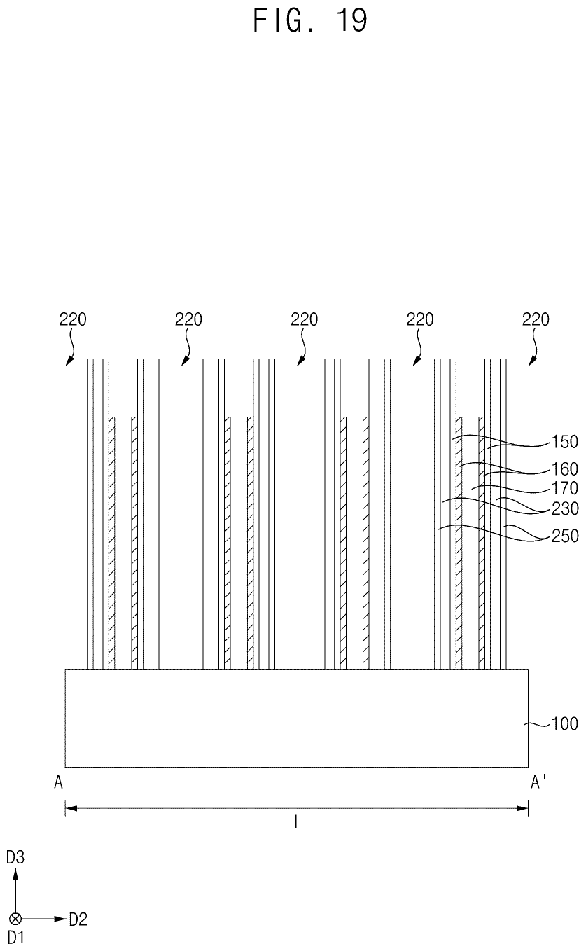

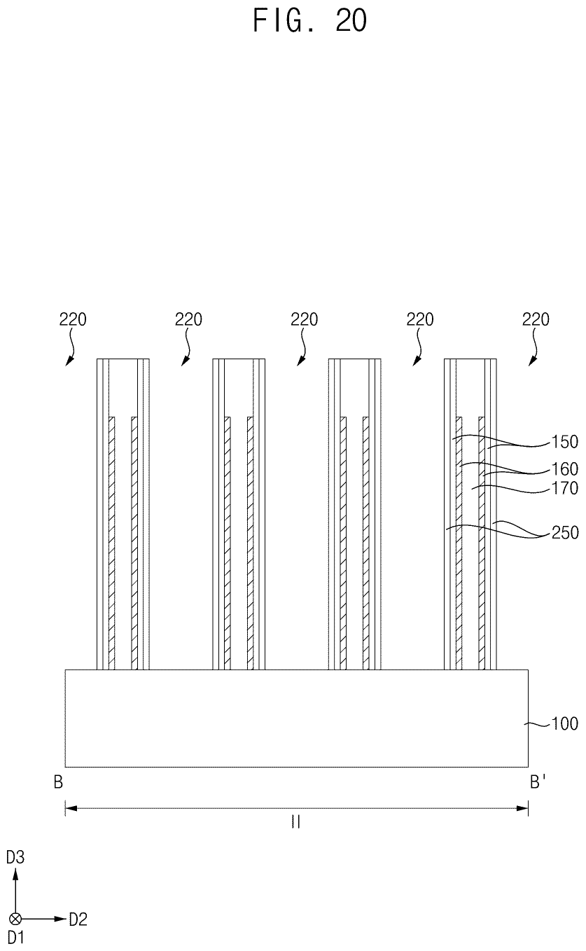

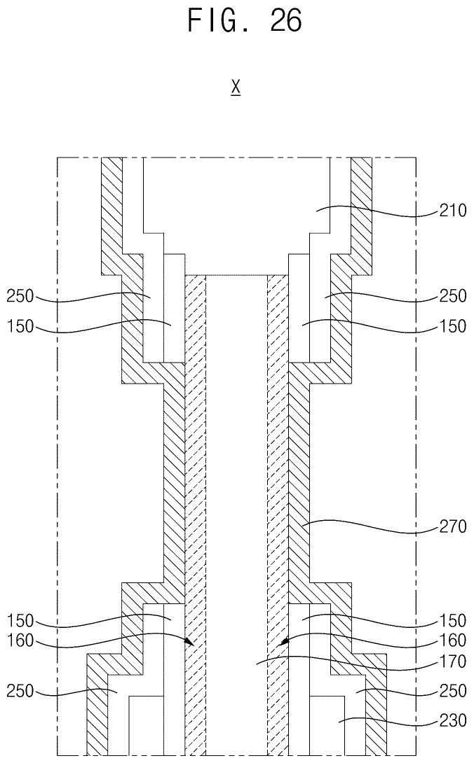

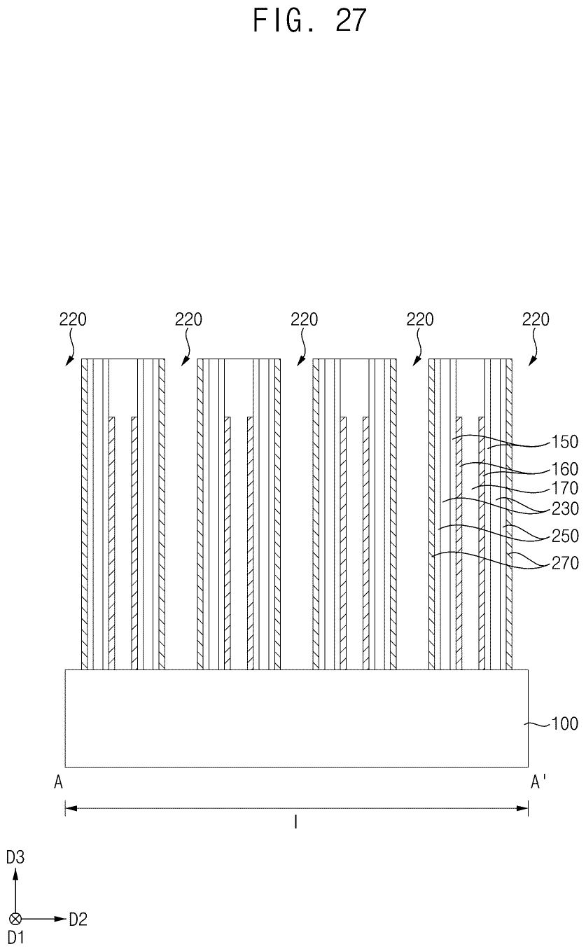

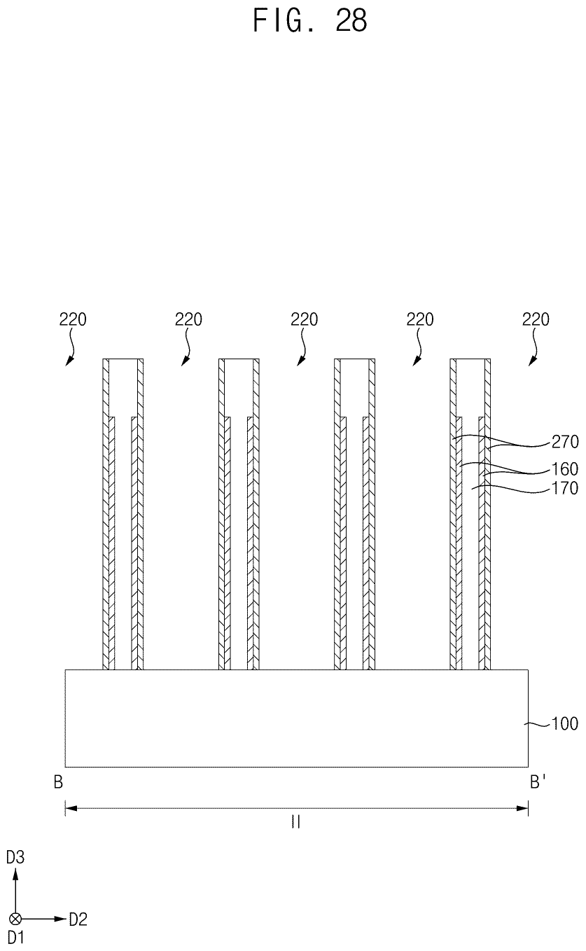

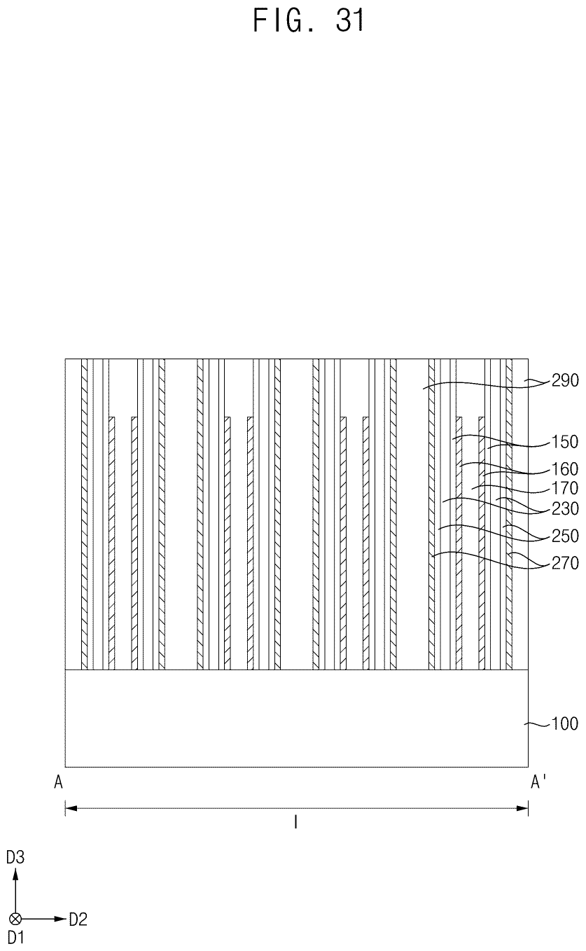

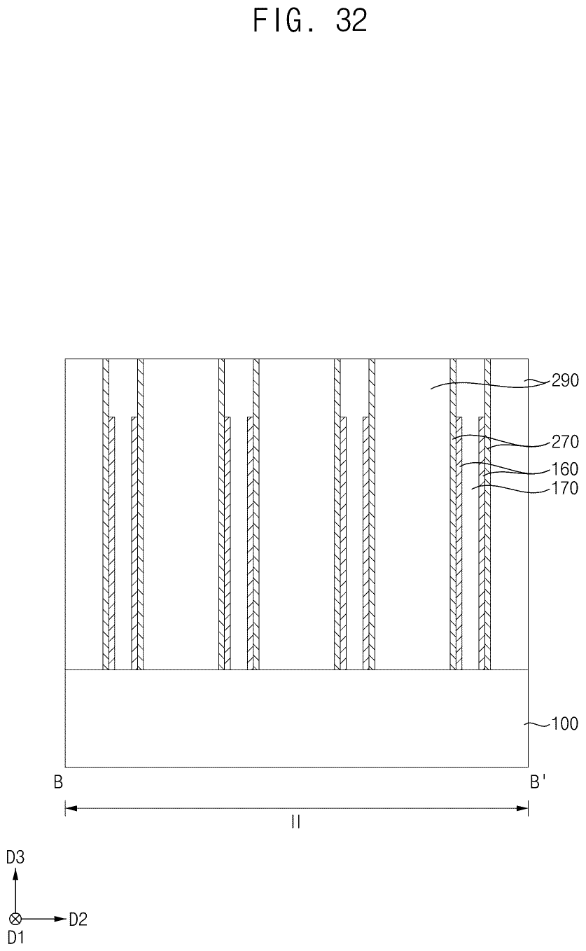

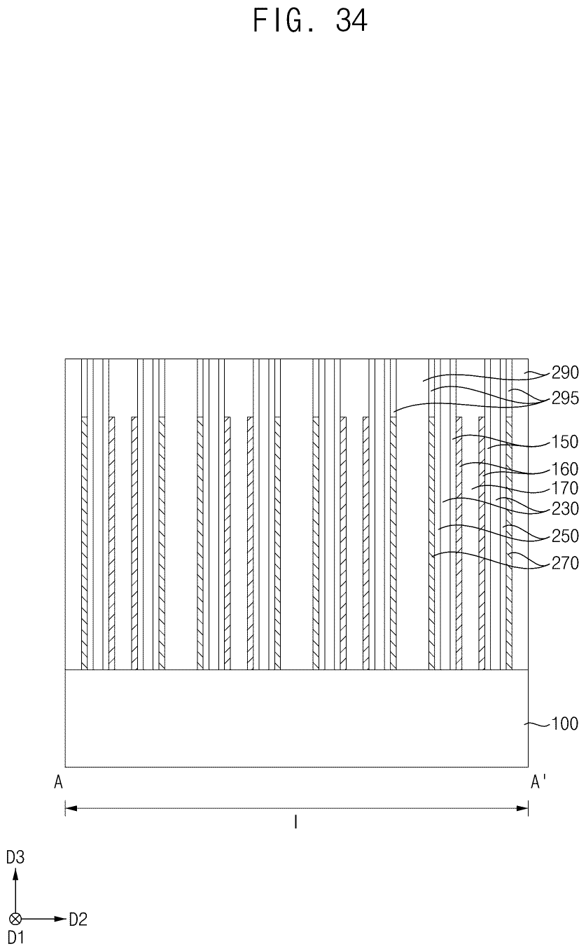

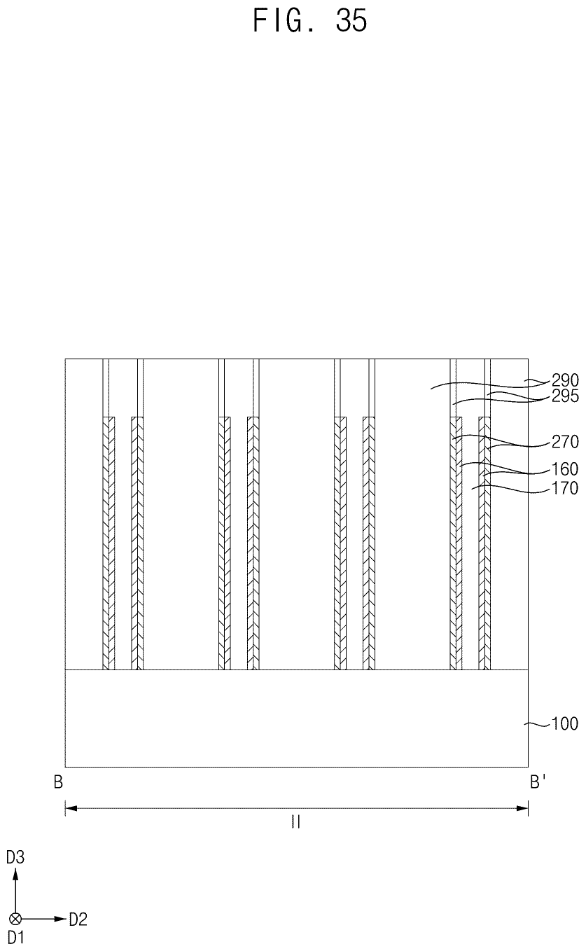

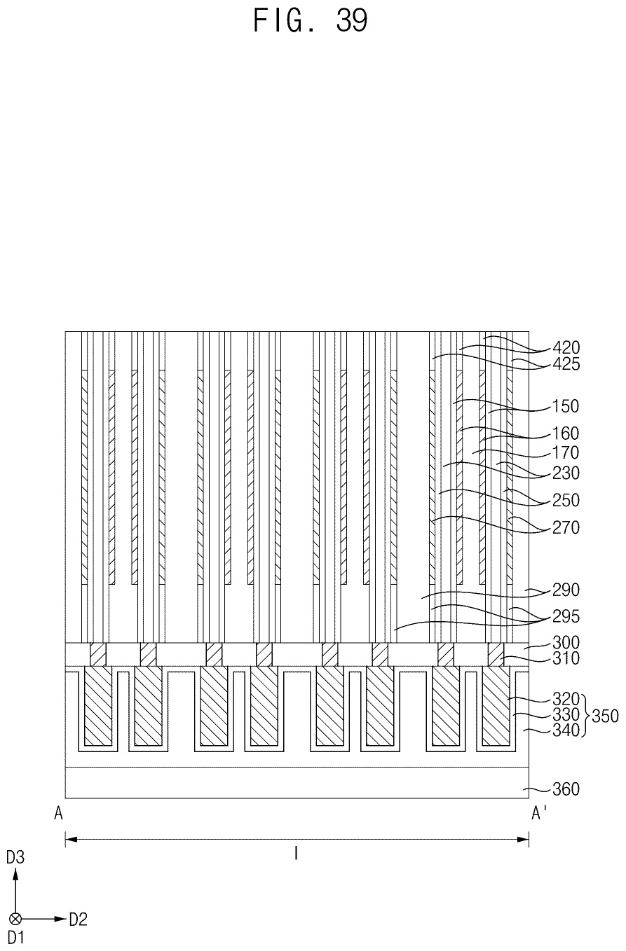

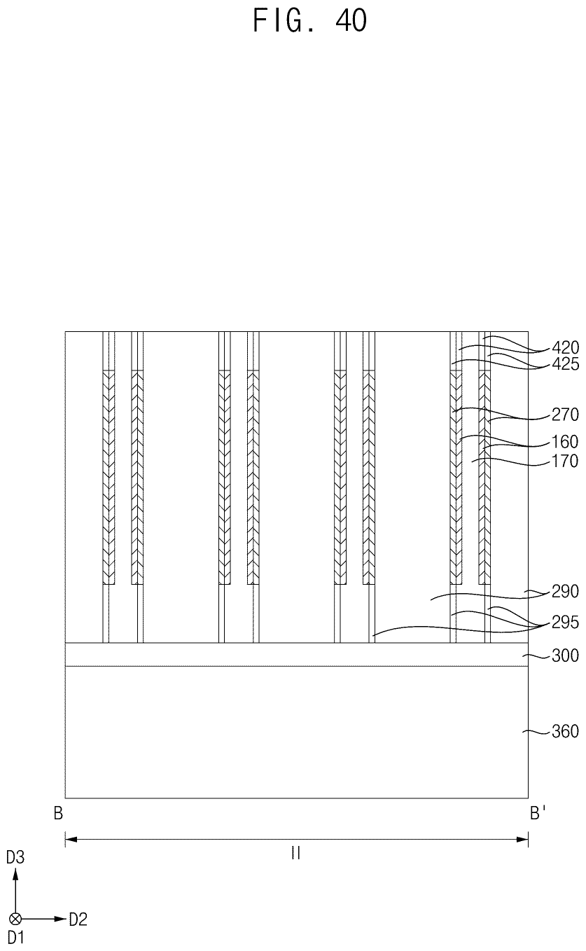

FIGS. 4 to 44 are plan views and cross-sectional views illustrating a method of manufacturing a semiconductor device according to example embodiments. Specifically, FIGS. 4, 5, 7, 9, 11, 13, 15, 18, 21, 23, 25, 29, 30, 33, 36, 38, 41, and 43 are the plan views, FIGS. 10, 12, 14, 22, 24, and 26 are enlarged cross-sectional views of region X of corresponding plan views, FIGS. 6, 8, 16, 19, 27, 31, 34, 37, 39, 42, and 44 are cross-sectional views taken along lines A-A′, respectively, of corresponding plan views, and FIGS. 17, 20, 28, 32, 35, and 40 are cross-sectional views taken along lines B-B′, respectively, of corresponding plan views.

Referring to FIG. 4, a first sacrificial layer 110 including a first opening 120 may be formed on a first substrate 100 that includes a first region I and the second region II. The first opening 120 may be in the second region II.

In example embodiments, the first opening 120 may be one of a plurality of first openings 120 spaced apart from each other in the second direction D2 on the second region II of the first substrate 100. In a plan view, each of the first openings 120 may have a rectangular shape in which a length in the first direction D1 may be longer than a length in the second direction D2, but the shape of the first opening 120 is not limited thereto.

The second sacrificial pattern 135 may be formed in the first opening 120. The second sacrificial pattern 135 may be formed by forming a second sacrificial layer on the first substrate 100 to a sufficient height to fill the first opening 120 and performing a planarization process on an upper portion of the second sacrificial layer until an upper surface of the first sacrificial layer 110 is exposed. The planarization process may include, for example, a chemical mechanical polishing (CMP) process and/or an etch back process.

In example embodiments, the second sacrificial pattern 135 may include a material having a selectivity (e.g., etch selectivity) with respect to the first sacrificial layer 110.

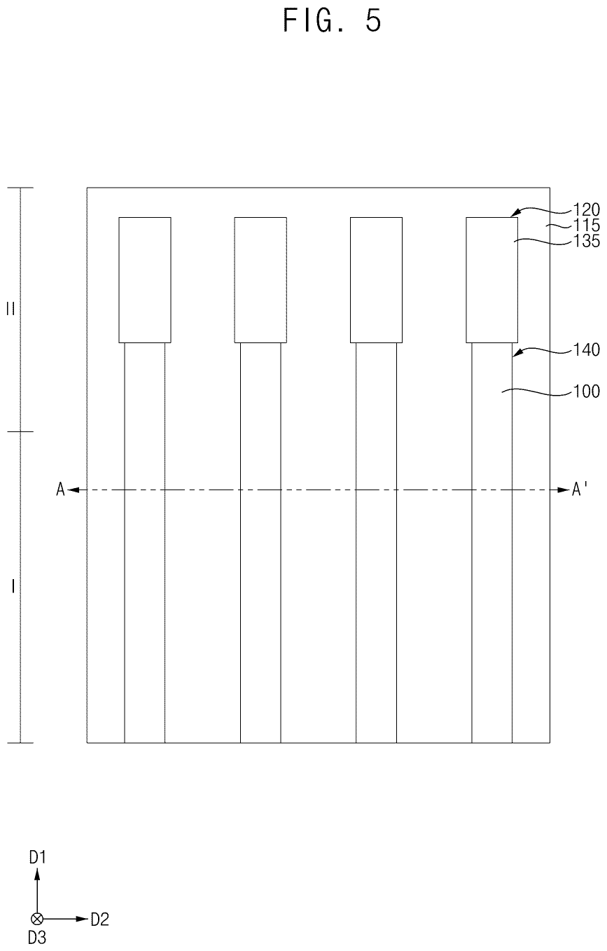

Referring to FIGS. 5 and 6, the first sacrificial layer 110 may be partially removed to form a second opening 140 that may expose an upper surface of the first substrate 100 and extend in the first direction D1. The first sacrificial layer 110 may be transformed into a first sacrificial pattern 115 (by the partial removal for the second opening 140).

The second opening 140 may expose (a portion of) a sidewall in the first direction D1 of the second sacrificial pattern 135. In example embodiments, the second opening 140 may be one of a plurality of second openings 140 spaced apart from each other in the second direction D2.

In example embodiments, a width in the second direction D2 of the second opening 140 may be smaller than a width in the second direction D2 of the second sacrificial pattern 135 in the first opening 120.

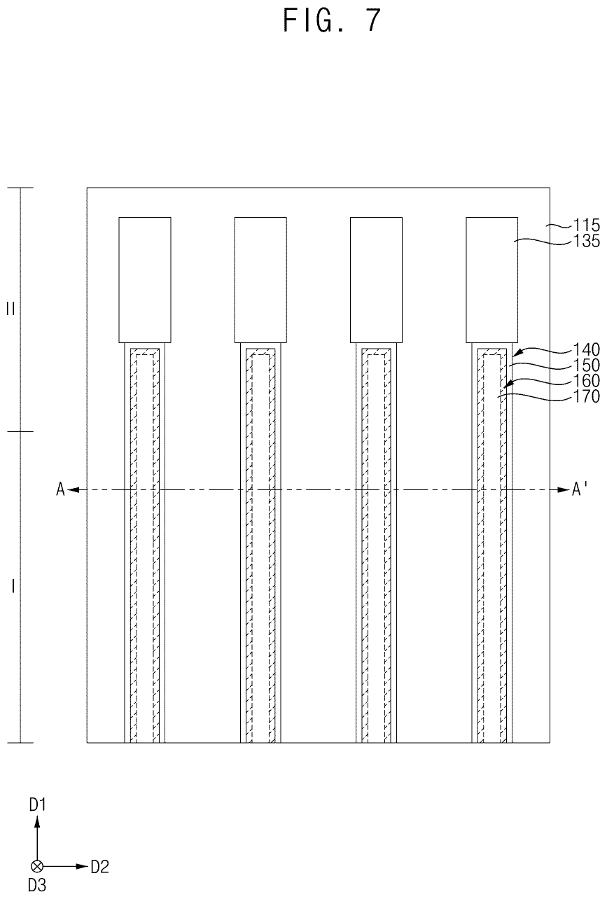

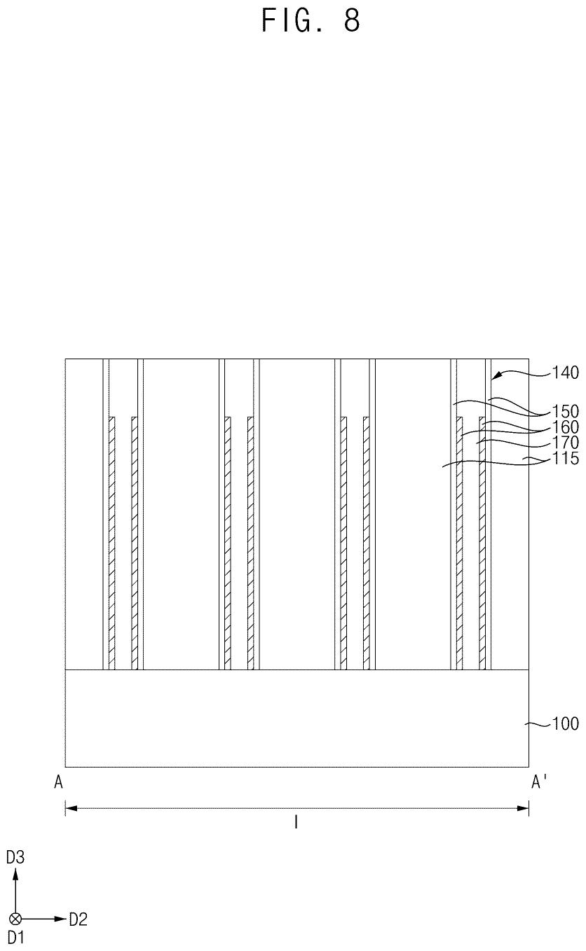

Referring to FIGS. 7 and 8, a first gate insulation pattern 150 and a first gate electrode 160 may be sequentially formed on a sidewall of the second opening 140, and a first insulation pattern 170 may be formed to fill (the remaining portion of) the second opening 140.

The first gate insulation pattern 150 may be formed by forming a first gate insulation layer on a bottom (e.g., a lower surface) and a sidewall of the second opening 140 and upper surfaces of the first and second sacrificial patterns 115 and 135, and performing an anisotropic etching process on the first gate insulation layer.

In example embodiments, the first gate insulation pattern 150 may include a first portion and a second portion. The first portion of the first gate insulation pattern 150 may be formed on a sidewall in the first direction D1 of the second opening 140, that is, a sidewall in the first direction D1 of the second sacrificial pattern 135. The second portion of the first gate insulation pattern 150 may extend in the first direction D1 from end portions in the second direction D2 of the first portion of the first gate insulation pattern 150 along sidewalls in the second direction D2 of the second opening 140, that is, sidewalls in the second direction D2 of the first sacrificial patterns 115.

The first gate electrode 160 may be formed by forming a first gate electrode layer on a bottom (e.g., a lower surface) of the second opening 140, an inner sidewall and an upper surface of the first gate insulation pattern 150 and the upper surfaces of the first and second sacrificial patterns 115 and 135 and performing an anisotropic etching process on the first gate electrode layer.

In example embodiments, the first gate electrode 160 may include a third portion and a fourth portion. The third portion of the first gate electrode 160 may be formed on a lower portion of a sidewall in the first direction D1 of the first portion of the first gate insulation pattern 150. In some embodiments, the third portion may not be on an upper portion of the sidewall in the first direction D1 of the first portion of the first gate insulation pattern 150. The fourth portion of the first gate electrode 160 may extend along lower portions of sidewalls facing each other in the second direction D2 of the second portions of the first gate insulation pattern 150. In some embodiments, the fourth portion may not be on an upper portion of the sidewalls facing each other in the second direction D2 of the second portions of the first gate insulation pattern 150.

The first insulation pattern 170 may be formed by forming a first insulation layer on the first gate insulation pattern 150, the first gate electrode 160, and the first and second sacrificial patterns 115 and 135 to fill a remaining portion of the second opening 140 to a sufficient height, and performing a planarization process on an upper portion of the first insulation layer until the upper surfaces of the first and second sacrificial patterns 115 and 135 and the first gate insulation pattern 150 are exposed.

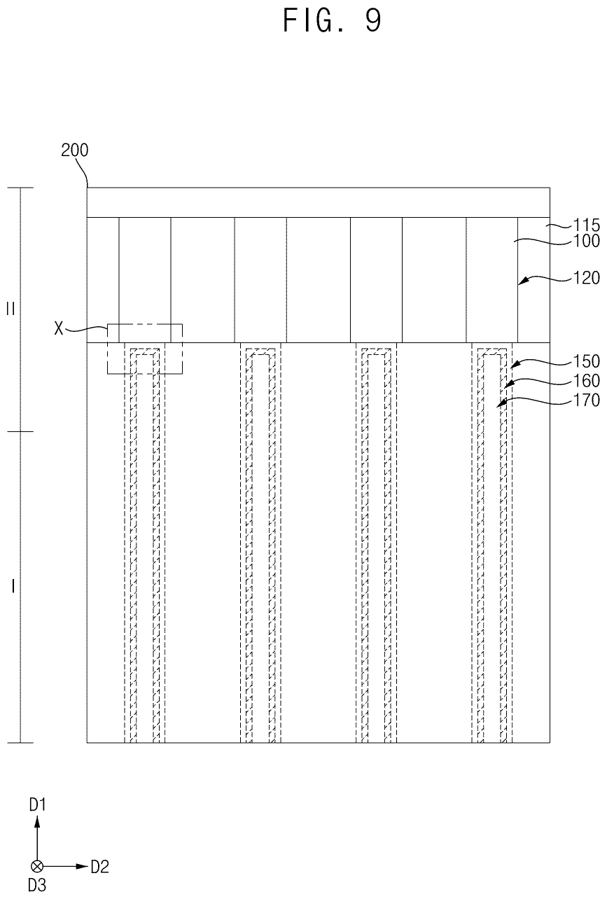

Referring to FIGS. 9 and 10, the first mask 200 including a third opening may be formed on the first and second sacrificial patterns 115 and 135, the first insulation pattern 170, and the first gate insulation pattern 150.

In example embodiments, the third opening may be formed on the second region II of the first substrate 100 and extend in the second direction D2 to expose the upper surfaces of the second sacrificial patterns 135 and the first sacrificial pattern 115 there between.

The second sacrificial pattern 135 exposed by the third opening may be removed to form the first opening 120 again. An opposite sidewall in the first direction D1 of the first portion of the first gate insulation pattern 150 may be exposed by the first opening 120. In example embodiments, the second sacrificial pattern 135 may be removed by a wet etching process.

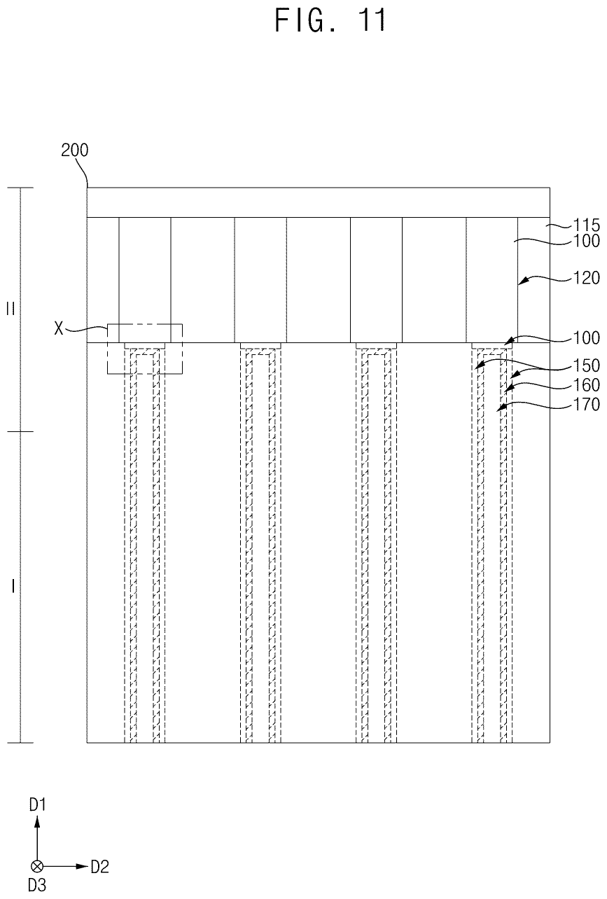

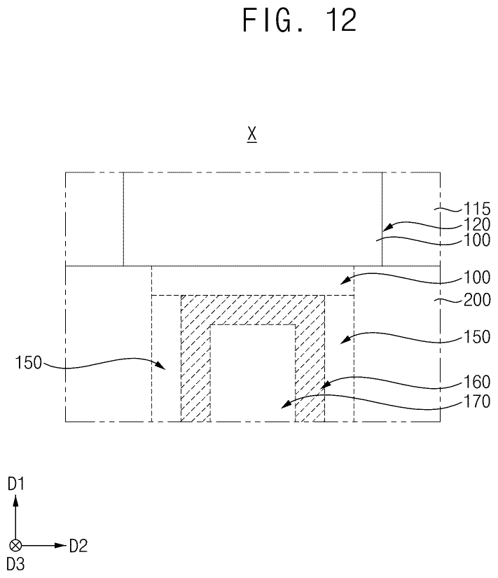

Referring to FIGS. 11 and 12, the first portion of the first gate insulation pattern 150 exposed by the first opening 120 may be removed.

Accordingly, the second portions of the first gate insulation pattern 150 may be separated from each other rather than connected to each other by the first portion of the first gate insulation pattern 150. In example embodiments, the first portion of the first gate insulation pattern 150 may be removed by performing a wet etching process.

As the first portion of the first gate insulation pattern 150 is removed, a sidewall in the first direction D1 of the third portion of the first gate electrode 160 may be exposed (e.g., exposed from the first gate insulation pattern 150 and exposed by the first opening 120).

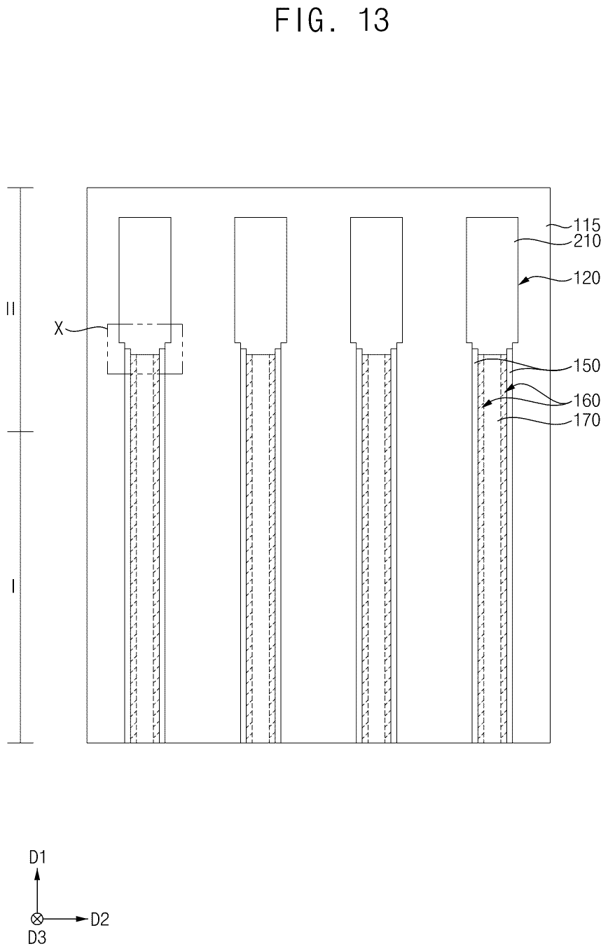

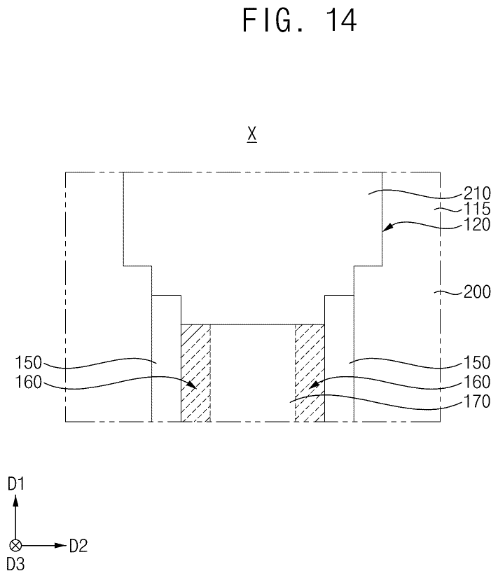

Referring to FIGS. 13 and 14, the third portion of the first gate electrode 160 exposed by the first opening 120 may be removed.

Accordingly, the fourth portions of the first gate electrode 160 may be separated from each other rather than connected to each other by the third portion of the first gate electrode 160. In example embodiments, the third portion of the first gate electrode 160 may be removed by performing a wet etching process.

After removing the first mask 200, the gate isolation pattern 210 may be formed in the first opening 120.

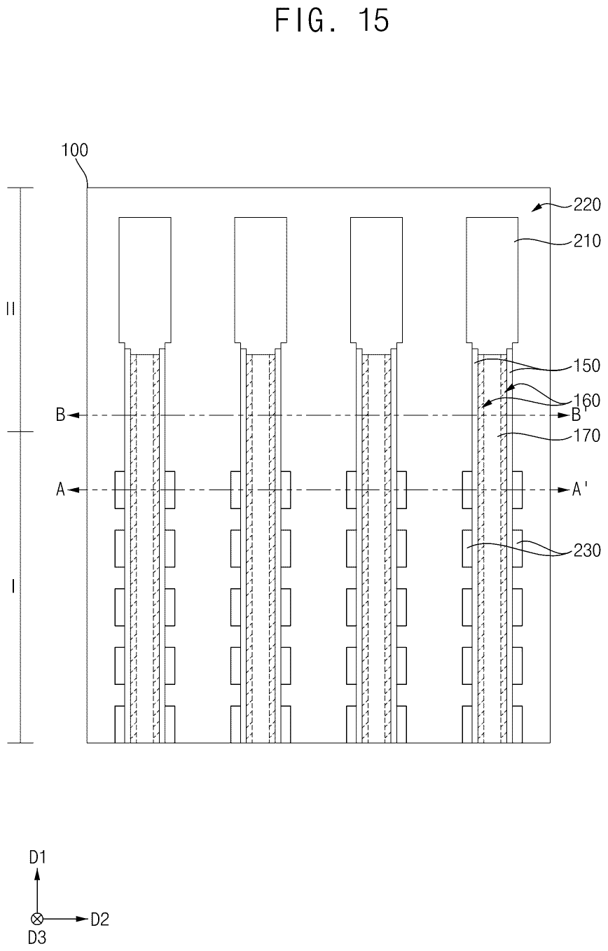

Referring to FIGS. 15 to 17, the first sacrificial pattern 115 may be removed. Thus, a fourth opening 220 exposing the upper surface of the first substrate 100, an outer sidewall of the first gate insulation pattern 150, and a sidewall the gate isolation pattern 210 may be formed.

A plurality of channels 230 may be formed along the outer sidewall of the first gate insulation pattern 150 to be spaced apart from each other in the first direction D1 on the first region I of the first substrate 100.

In example embodiments, the channel 230 may be formed by forming a channel layer on the upper surface of the first substrate 100, the outer sidewall of the first gate insulation pattern 150, and the sidewall the gate isolation pattern 210 exposed by the fourth opening, performing an anisotropic etching process to separate the channel layer into a plurality of portions each of which extends in the first direction D1 along the outer sidewall of the first gate insulation pattern 150, forming a first mold on the channel layer, forming second masks spaced apart from each other in the first direction D1 on the first mold, each of the second masks extending in the first direction D1, and performing a dry etching process using the second masks to pattern the first mold and the channel layer. The first mold may be removed.

Hereinafter, 1) the first insulation pattern 170, 2) the first gate electrode 160, the first gate insulation pattern 150, and the channels 230 sequentially formed on the opposite sidewalls in the second direction D2 of the first insulation pattern 170, and 3) the gate isolation pattern 210 formed on sidewalls in the first direction D1 of 1) and 2) may be together referred to as a preliminary first extension structure.

In example embodiments, the preliminary first extension structure may extend in the first direction D1. The preliminary first extension structure may be one of a plurality of preliminary first extension structures spaced apart from each other in the second direction D2.

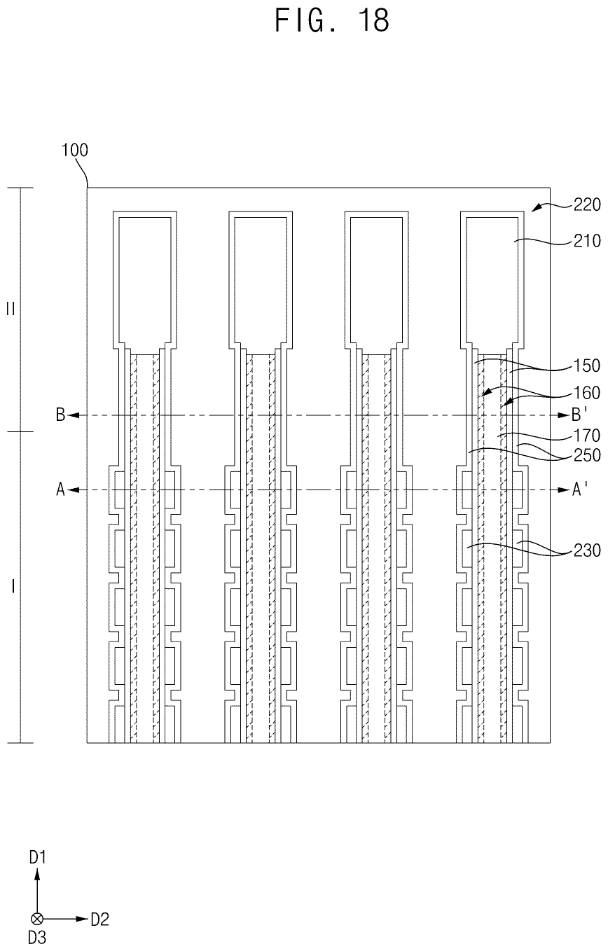

Referring to FIGS. 18 to 20, a second gate insulation pattern 250 may be formed on a sidewall of the preliminary first extension structure, that is, the sidewall of the gate isolation pattern 210, the outer sidewall of the first gate insulation pattern 150 and the sidewalls of the channels 230.

In example embodiments, the second gate insulation pattern 250 may be formed by forming second gate insulation layer on the upper surface of the first substrate 100 and the sidewall and an upper surface of the preliminary first extension structure, and performing an anisotropic etching process thereon. The second gate insulation pattern 250 may form a gate insulation pattern structure together with the first gate insulation pattern 150.

In example embodiments, the second gate insulation pattern 250 may include a fifth portion and a sixth portion. The fifth portion of the second gate insulation pattern 250 may be formed on a sidewall in the first direction D1 of the gate isolation pattern 210. The sixth portion of the second gate insulation pattern 250 may (generally) extend in the first direction D1 from end portions in the second direction D2 of the fifth portion of the second gate insulation pattern 250 along the sidewalls in the second direction D2 of the preliminary first extension structure. In some embodiments, in a plan view, the second gate insulation pattern 250 may be formed along the profile (e.g., sidewalls in the first and second direction D1 and D2) of the preliminary first extension structure.

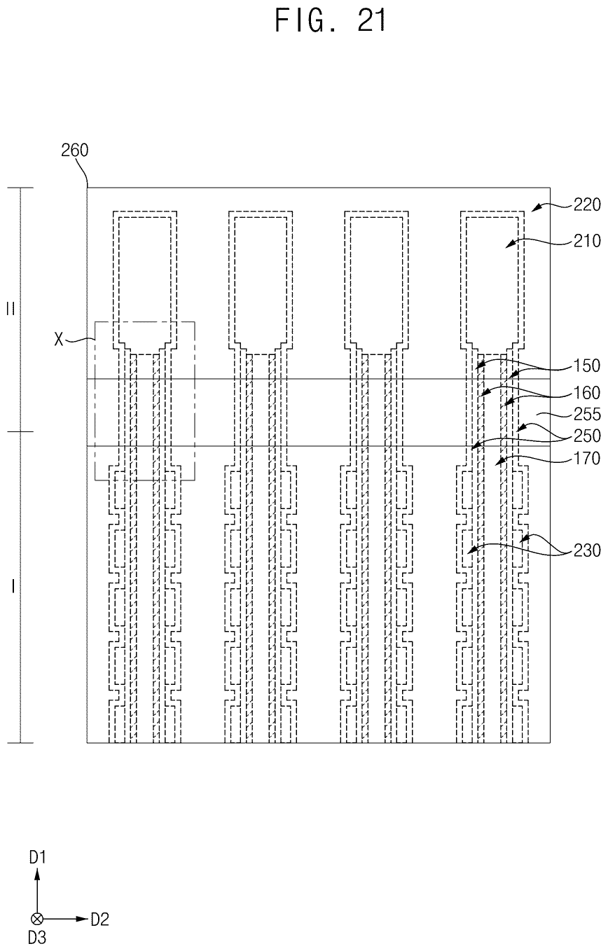

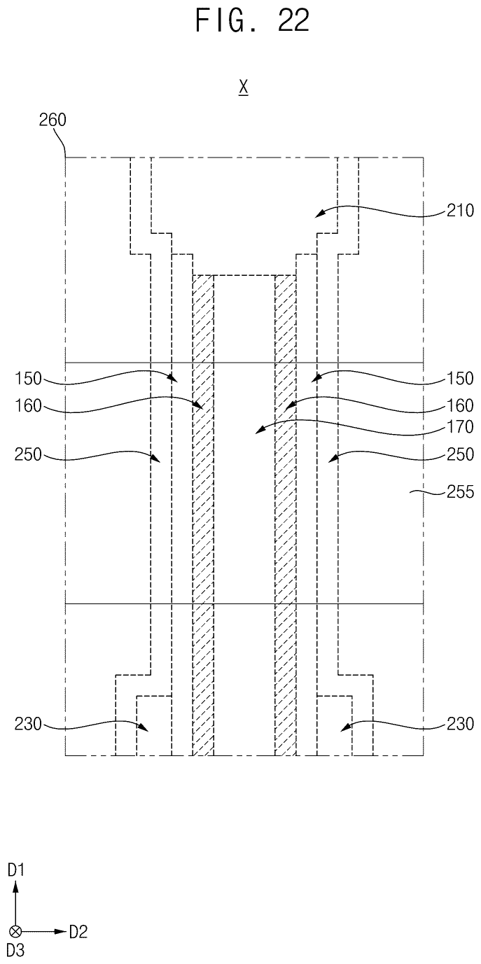

Referring to FIGS. 21 and 22, a second mold layer 255 may be formed to fill the fourth opening 220 to a sufficient height, and a third mask 260 including a fifth opening may be formed on the second mold layer 255.

In example embodiments, the fifth opening may extend in the second direction D2 near a boundary of the first and second regions I and II of the first substrate 100. The fifth opening may overlap in the third direction D3 with a portion of the preliminary first extension structure between the gate isolation pattern 210 and one of the channels 230 that is closest to the gate isolation pattern 210 in the first direction D1. That is, the fifth opening may overlap in the third direction D3 with portions of the first insulation pattern 170, the first gate electrode 160, the first gate insulation pattern 150, and the second gate insulation pattern 250 between the gate isolation pattern 210 and one of the channels 230 that is closest to the gate isolation pattern 210 in the first direction D1.

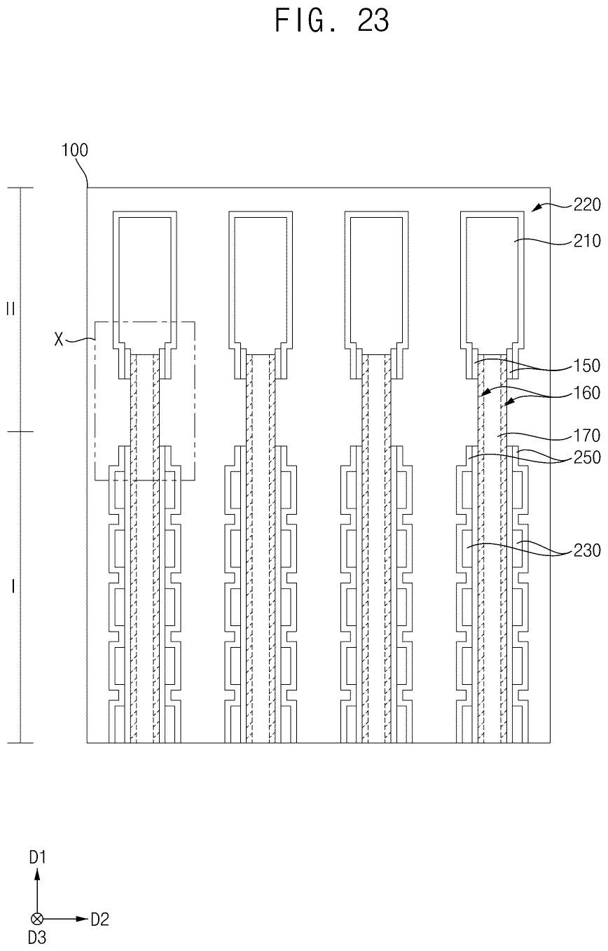

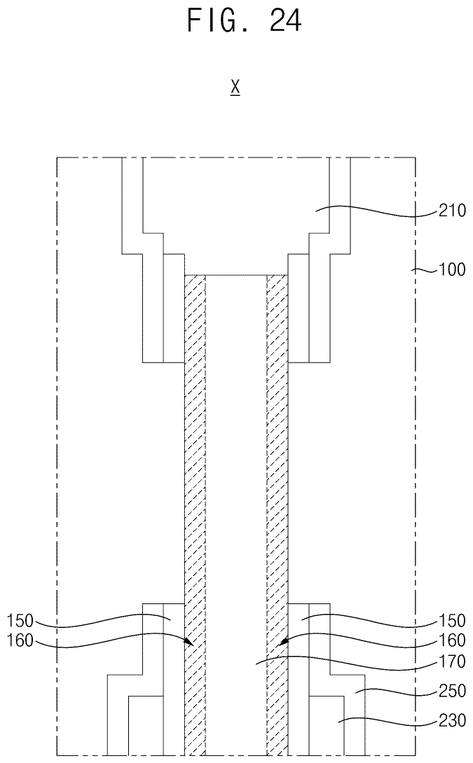

Referring to FIGS. 23 and 24, an etching process using the third mask 260 may be performed to remove portions of the second mold layers and the first and second gate insulation patterns 150 and 250 that overlap the fifth opening in the third direction D3. Accordingly, an outer sidewall of the first gate electrode 160 may be partially exposed.

The third mask 260 and the remaining second mold layer 255 may be removed, and thus the fourth opening 220 may be formed again.

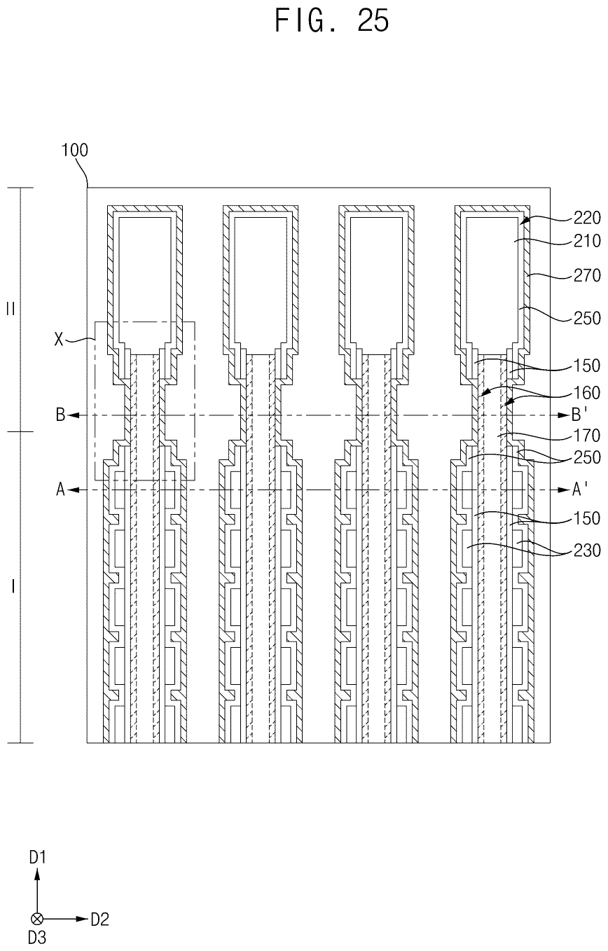

Referring to FIGS. 25 to 28, a second gate electrode 270 may be formed on the exposed outer sidewall of the first gate electrode 160 and the sidewall of the second gate insulation pattern 250. Accordingly, the second gate electrode 270 may be electrically connected to the exposed outer sidewall of the first gate electrode 160. For example, the second gate electrode 270 may be in (direct) contact with the first gate electrode 160.

The second gate electrode 270 may form a gate electrode structure together with the first gate electrode 160, and the gate electrode structure may form a first gate structure together with the gate insulation pattern structure.

In example embodiments, the second gate electrode 270 may include a seventh portion and an eighth portion. The seventh portion of the second gate electrode 270 may be formed on a sidewall in the first direction D1 of the fifth portion of the second gate insulation pattern 250. The eight portion of the second gate electrode 270 may (generally) extend in the first direction D1 from end portions in the second direction D2 of the seventh portion of the second gate electrode 270 along sidewalls in the second direction D2 of the sixth portion of the second gate insulation pattern 250 and the exposed outer sidewall of the first gate electrode 160. In some embodiments, in a plan view, the second gate electrode 270 may be formed along the profiles (e.g., sidewalls in the first and second directions D1 and D2) of the second gate insulation pattern 250 and the exposed first gate electrode 160.

In example embodiments, the second gate electrode 270 may be formed by forming a second gate electrode layer on the upper surface of the first substrate 100, the sidewall and an upper surface of the second gate insulation pattern 250 and the upper surface and a portion of the sidewall of the preliminary first extension structure, and performing an anisotropic etching process on the second gate electrode layer.

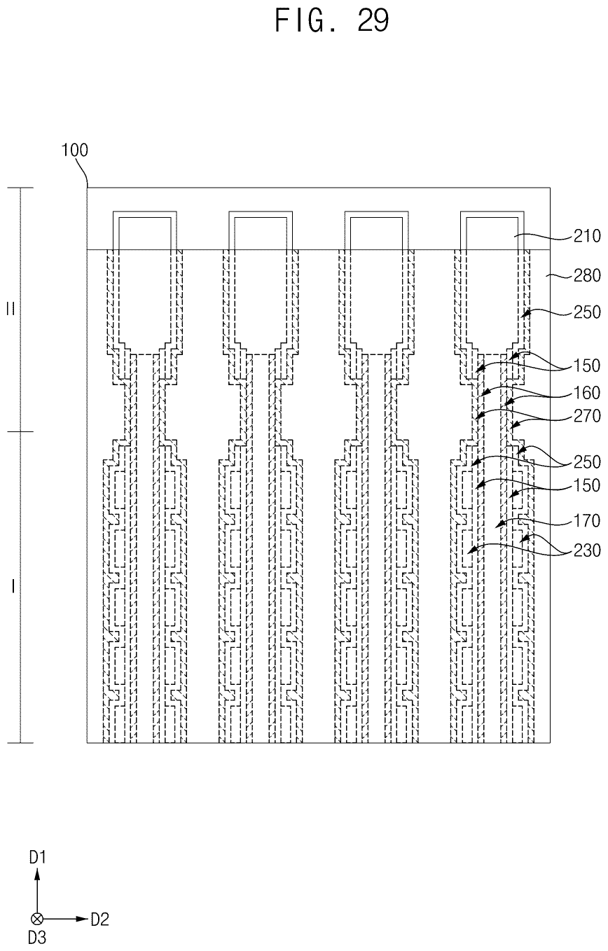

Referring to FIG. 29, a third mold layer may be formed to fill the fourth opening 220 to a sufficient height on the first substrate 100, and a fourth mask 280 including a sixth opening may be formed on the third mold layer.

In example embodiments, the sixth opening may extend in the second direction D2 on the second region II of the first substrate 100 and overlap an end portion in the first direction D1 of the gate isolation pattern 210, the fifth portion of the second gate insulation pattern 250 and the sixth portion of the second gate insulation pattern 250 adjacent to the fifth portion and the seventh portion of the second gate electrode 270 and the eighth portion of the second gate electrode 270 adjacent to the seventh portion.

An etching process using the fourth mask 280 may be performed to remove the third mold layer, the seventh portion of the second gate electrode 270 and the eighth portion adjacent to the seventh portion that overlap the sixth opening in the third direction D3. Accordingly, the eighth portions of the second gate electrode 270 may be separated from each other rather than connected to each other.

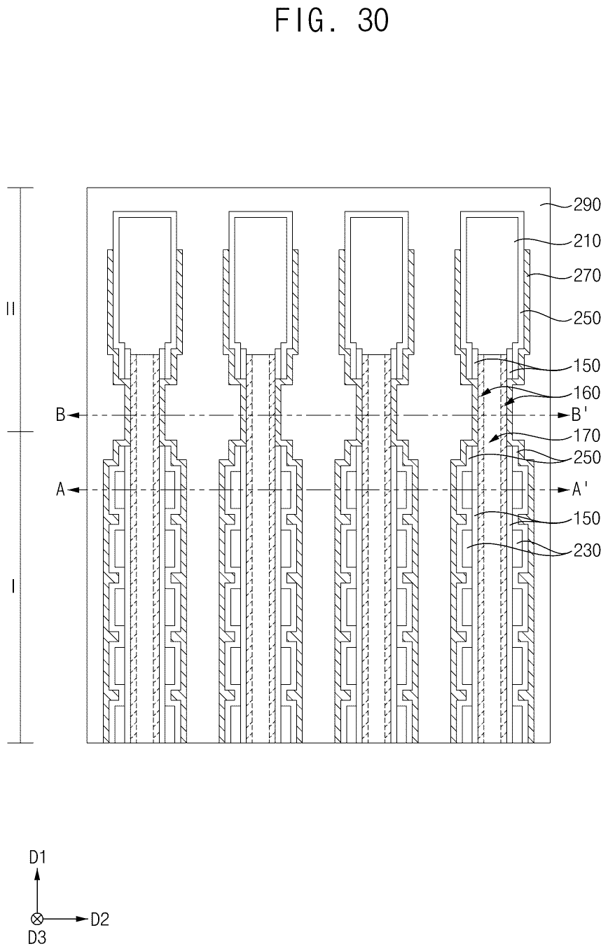

Referring to FIGS. 30 to 32, the fourth mask 280 and the remaining third mold layer may be removed to form the fourth opening 220 again, and a second insulation pattern 290 may be formed within the fourth opening 220.

In example embodiments, the second insulation pattern 290 may be formed by forming a second insulation layer on the first substrate 100, the second gate electrode 270, the second gate insulation pattern 250 and the preliminary first extension structure to fill the fourth opening 220, and performing a planarization process on the second insulation layer until the upper surface of the preliminary first extension structure is exposed.

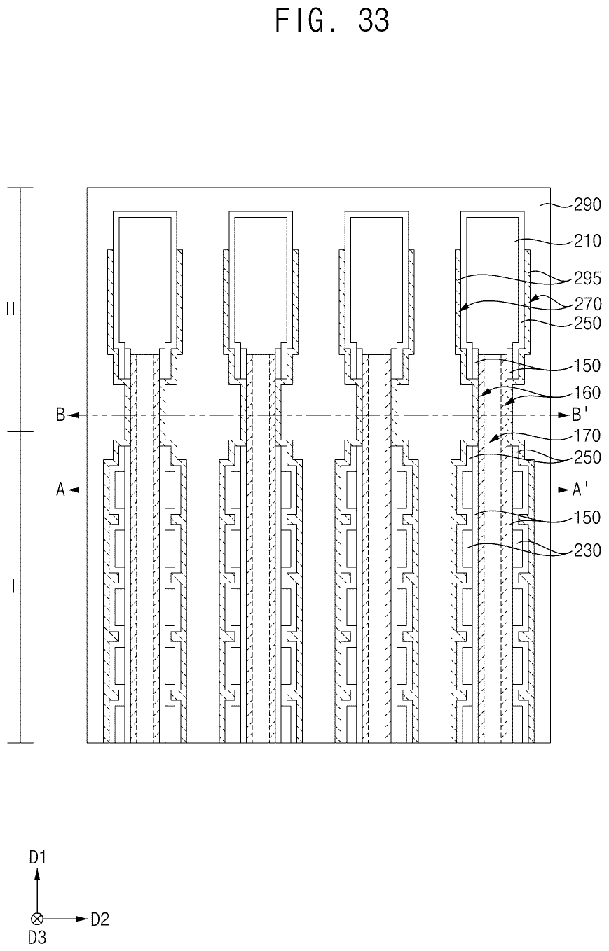

Referring to FIGS. 33 to 35, an upper portion of the second gate electrode 270 may be removed to form a first recess, and a third insulation pattern 295 may be formed within the first recess.

In example embodiments, a bottom of the first recess and the upper surface of the first gate electrode 160 may be (substantially) coplanar.

The third insulation pattern 295 may be formed by forming a third insulation layer on the preliminary first extension structure, the second gate electrode 270, the second gate insulation pattern 250, and the second insulation pattern 290, and a planarization process may be formed on an upper portion of the third insulation layer until an upper surface of the second insulation pattern 290 is exposed. In example embodiments, the third insulation pattern 295 may be formed to extend in the first direction D1 on each of the second gate electrodes 270.

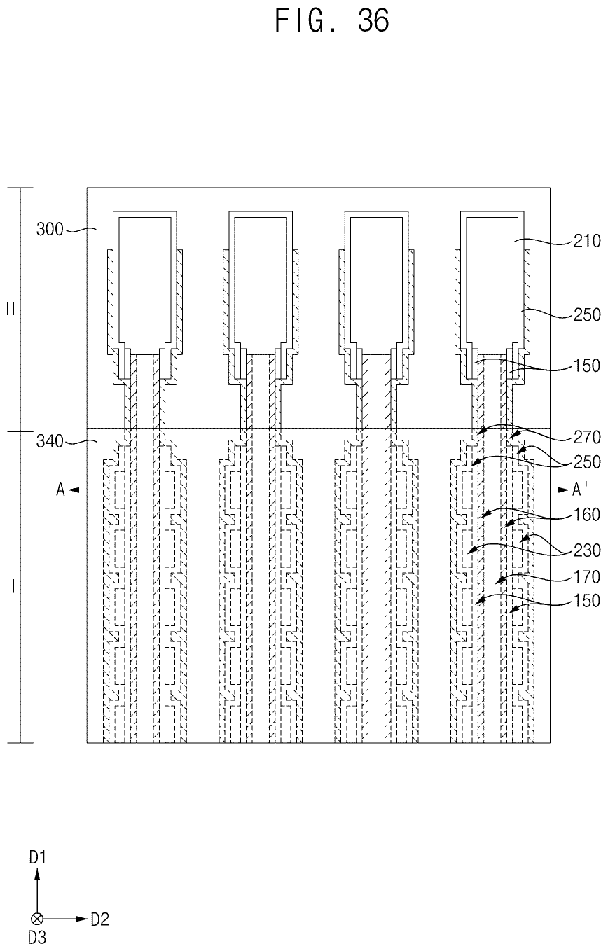

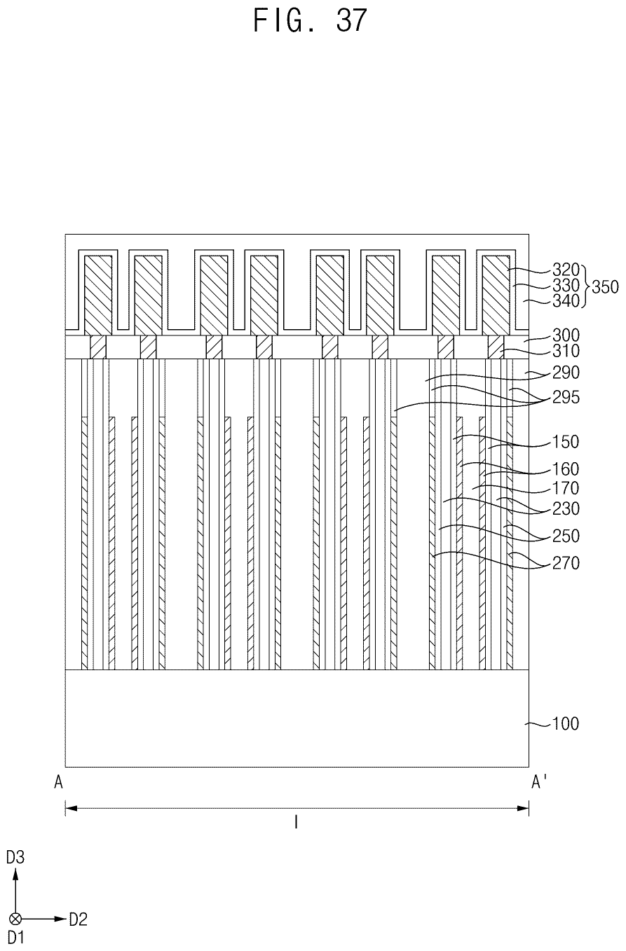

Referring to FIGS. 36 and 37, a first insulating interlayer 300 may be formed on the channels 230, the first and second gate insulation patterns 150 and 250 and the first, second, and third insulation patterns 170, 290, and 295, and a landing pad 310 may be formed to extend through the first insulating interlayer 300 to contact an upper surface of the channel 230.

In example embodiments, the landing pad 310 may be one of a plurality of landing pads 310 spaced apart from each other in the first and second directions D1 and D2 on the first region I of the first substrate 100. Each of the landing pads 310 may contact the upper surface of a corresponding one of the channels 230.

A first capacitor electrode 320 may be formed on the landing pad 310, a dielectric layer may be formed on the first capacitor electrode 320, the landing pad 310 and the first insulating interlayer 300, a second capacitor electrode layer may be formed on the dielectric layer, and portions of the second capacitor electrode layer and the dielectric layer on the second region II of the first substrate 100 may be removed to form a second capacitor electrode 340 and a dielectric pattern 330, respectively on the first region I of the first substrate 100.

In example embodiments, the first capacitor electrode 320 may be one of a plurality of first capacitor electrodes 320 spaced apart from each other in the first and second directions D1 and D2. Each of the first capacitor electrodes 320 may contact an upper surface of a corresponding one of the landing pads 310.

The first capacitor electrode 320, the dielectric pattern 330, and the second capacitor electrode 340 may together form a capacitor 350.

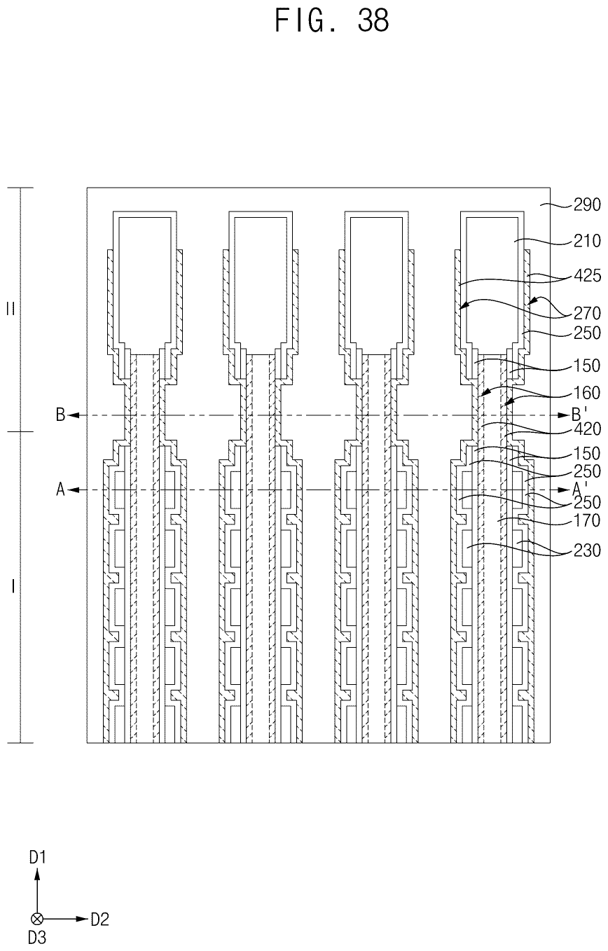

Referring to FIGS. 38 to 40, the first substrate 100 may be turned over.

Specifically, the second insulating interlayer 360 may be formed on the capacitor 350 and the first insulating interlayer 300, and a first bonding layer may be formed on the second insulating interlayer 360.

A second bonding layer may be formed on a second substrate having a first region I and a second regions II corresponding to the first region I and the second regions II of the first substrate 100, the second substrate and the second bonding layer may be turned over, and the first substrate 100 and the second substrate may be bonded to each other by attaching the second bonding layer to the first bonding layer.

The first substrate 100 and the second substrate bonded to the first substrate 100 may be turned over, the first substrate 100 may be removed, and upper surfaces the first and second gate electrodes 160 and 270, the channel 230, the first and second insulation patterns 170 and 290, and the first and second gate insulation patterns 150 and 250 may be exposed.

Upper portions of the first and second gate electrodes 160 and 270 may be removed to form a second recess and a third recess, respectively. A fourth insulation pattern 420 and a fifth insulation pattern 425 may be formed in the second and third recesses, respectively.

The second and third recesses may be formed by the same process or separate processes, and the fourth and fifth insulation patterns 420 and 425 may also be formed by the same process or separate processes. Accordingly, the fourth and fifth insulation patterns 420 and 425 may include the same material or different materials.

The fourth insulation pattern 420 may form a first insulation pattern structure together with the first insulation pattern 170, and the fifth insulation pattern 425 may form a second insulation pattern structure together with the second and third insulation patterns 290 and 295. Additionally, the first insulation pattern structure may form a first extension structure together with the first gate structure, the gate isolation pattern 210, and the channel 230.

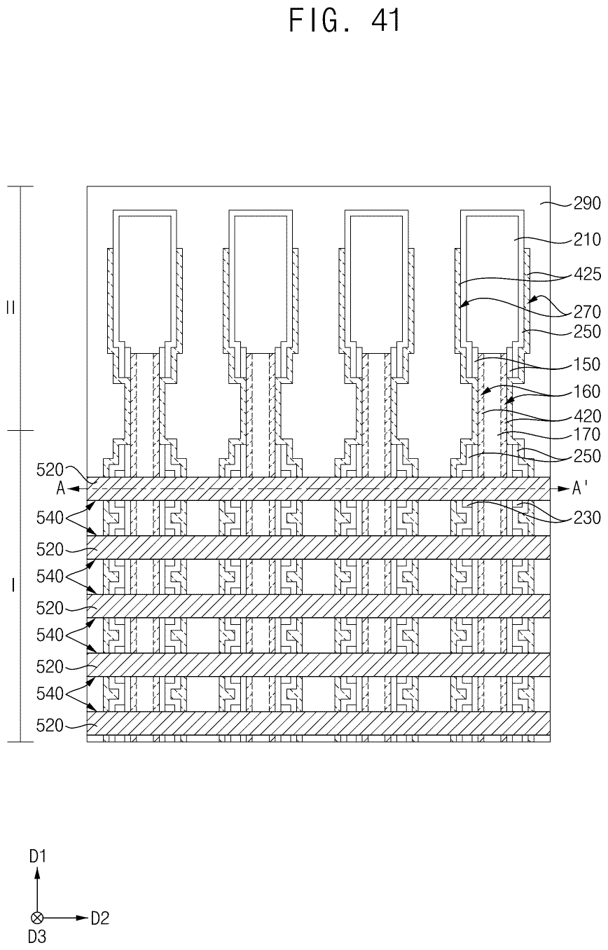

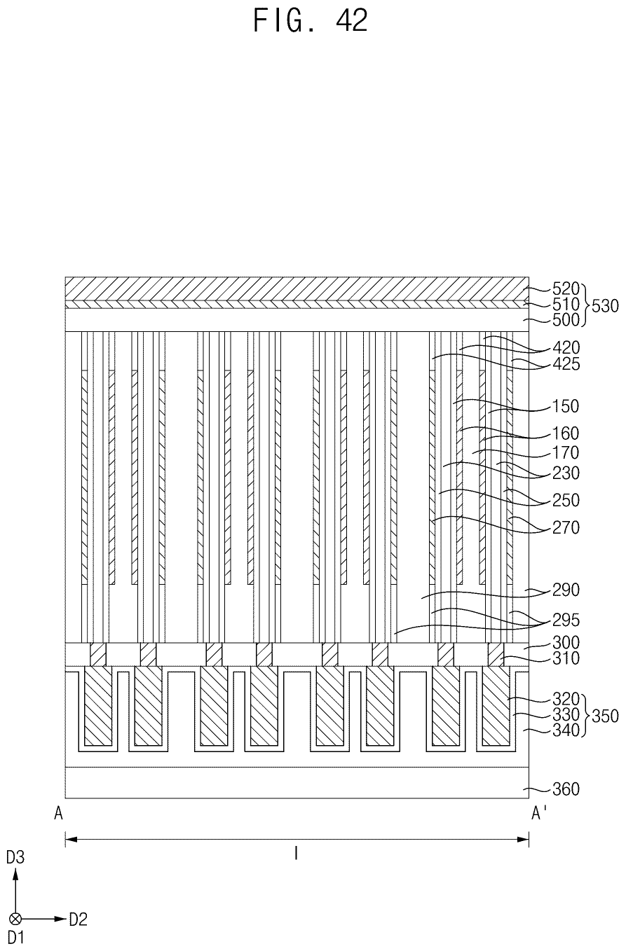

Referring to FIGS. 41 and 42, a first conductive layer, a barrier layer, and a second conductive layer may be formed on the fourth and fifth insulation patterns 420 and 425, the channel 230, and the first and second insulation patterns 170 and 290. The first conductive layer, the barrier layer, and the second conductive layer may be partially etched to form a first conductive pattern 500, a barrier pattern 510, and a second conductive pattern 520, respectively. The first conductive pattern 500, the barrier pattern 510, and the second conductive pattern 520 may together form a bit line structure 530.

In example embodiments, the bit line structure 530 may extend in the second direction D2 on the first region I of the second substrate, and the bit line structure 530 may be one of a plurality of bit line structures 530 spaced apart from each other in the first direction D1.

During the etching process, upper portions of the channel 230, the first and second insulation patterns 170 and 290, and the first and second gate insulation patterns 150 and 250 may also be partially removed. Accordingly, a fourth recess 540 exposing the upper surfaces of the channel 230, the first and second insulation patterns 170 and 290, and the first and second gate insulation patterns 150 and 250 may be formed between the bit line structures 530.

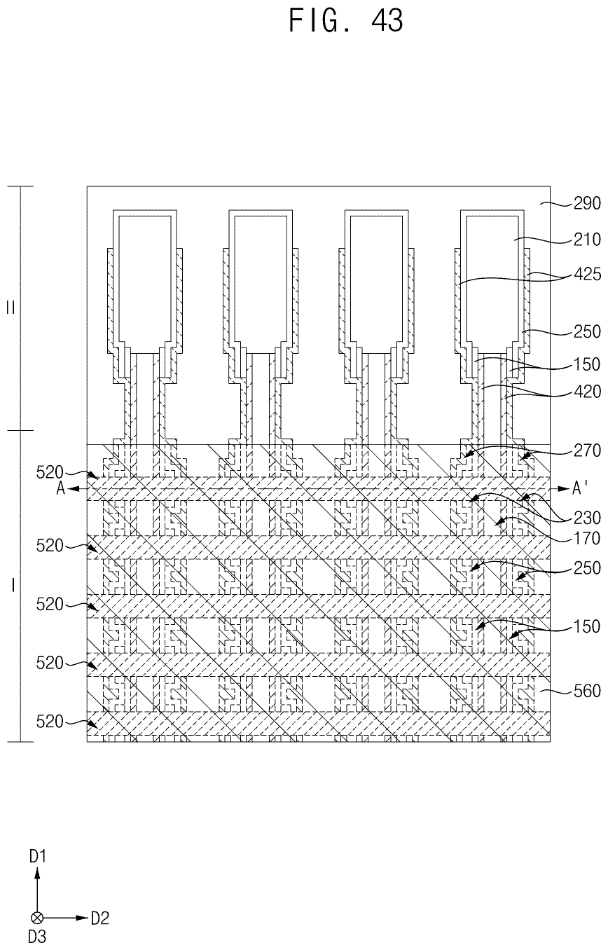

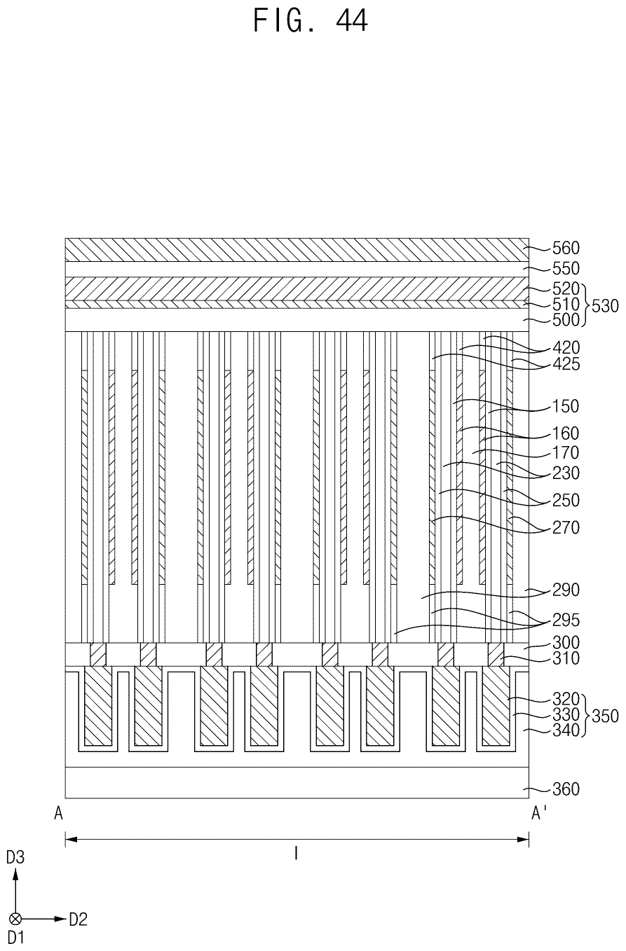

Referring to FIGS. 43 and 44, a sixth insulation layer may be formed on the bit line structure 530, the fourth and fifth insulation patterns 420 and 425, the channel 230, and the first and second insulation patterns 170 and 290, a bit line shield layer may be formed on the sixth insulation layer to fill the fourth recess 540 so that an upper surface of the bit line shield layer is higher than an uppermost surface of the sixth insulation layer, and portions of the bit line shield layer and the sixth insulation layer on the second region II of the second substrate may be removed to form a bit line shield structure 560 and a sixth insulation pattern 550.

The bit line shield structure 560 may include a bit line shield plate formed above an upper surface of the bit line structure 530 and a bit line shield fin formed below the upper surface of the bit line structure 530. In example embodiments, the bit line shield plate may have a flat shape. In example embodiments, the bit line shield fin may extend in the second direction D2 and the bit line shield fin may be one of a plurality of bit line shield fins spaced apart from each other in the first direction D1.

Referring to FIGS. 1 to 3 again, after turning over the second substrate, the second substrate and the first and second bonding layer may be removed to expose the upper surface of the second insulating interlayer 360.

Regions overlapping the first and second regions I and II of the second substrate in the third direction D3 may be referred to as a first region and a second region I and II, respectively.

A third insulating interlayer 600 may be formed on a bit line shield structure 560 on the first region I, and on the fourth and fifth insulation patterns 420 and 425, the first and second insulation patterns 170 and 290, and first and second gate insulation patterns 150 and 250 on the second region II. A contact plug 610 may be formed on the second region II to extend through the third insulating interlayer 600 and the fifth insulation pattern 425 to contact the upper surface of the second gate electrode 270.

In the method of manufacturing the semiconductor device, the first gate insulation pattern 150 and the first gate electrode 160 may be formed, the channel 230 may be formed on a portion of the first sidewall of the first gate insulation pattern 150, and the second gate insulation pattern 250 may be formed along a remaining portion of the first sidewall of the first gate insulation pattern 150 and the (remaining) sidewalls of the channel 230.

Accordingly, compared to the case where the channel is formed first and the gate structure is formed afterwards to surround the sidewall of the channel, the channel 230 may be supported by the first gate insulation pattern 150, thereby preventing the semiconductor device from bending or collapsing during the manufacturing process.

The sidewall of the first gate electrode 160 may be partially exposed by removing a portion of the first and second gate insulation patterns 150 and 250, and the second gate electrode 270 may be formed along the exposed sidewall of the first gate electrode 160 and the sidewall of the second gate insulation pattern 250. Accordingly, the first gate electrode 160 and the second gate electrode 270 may be electrically connected to (e.g., in contact with) each other, and thus, same voltage (e.g., same voltage value) may be applied (simultaneously) to the first and second gate electrodes 160 and 270 by the contact plug 610 which may be in contact with the second gate electrode 270.

In addition, the first and second gate insulation patterns 150 and 250 and the first and second gate electrodes 160 and 270 of the first gate structure may be formed by separate processes. Thus, by adjusting materials and/or thickness of the first and second gate insulation patterns 150 and 250 and the first and second gate electrodes 160 and 270 of the first gate structure, the desired threshold voltage value of the transistor including the first gate structure may be easily obtained.

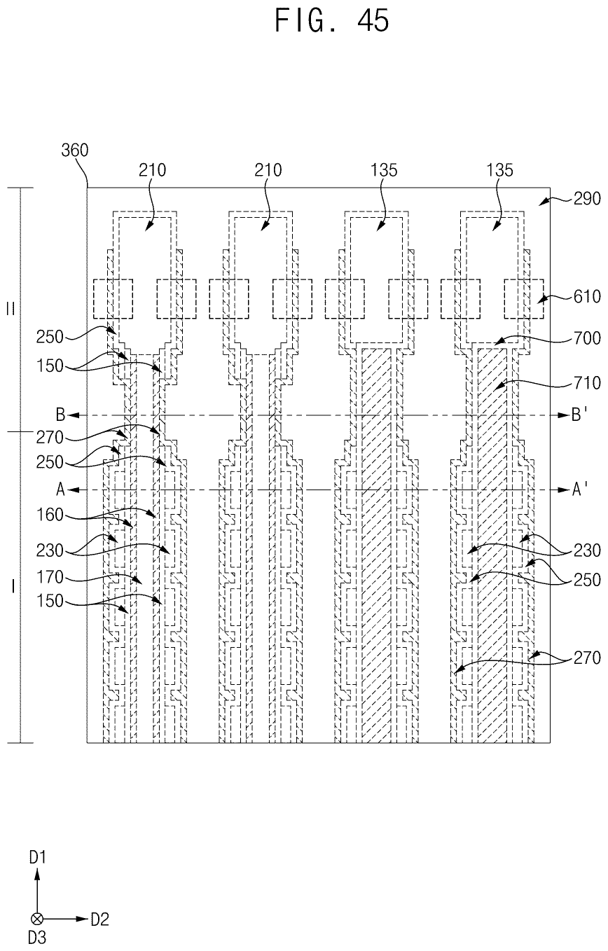

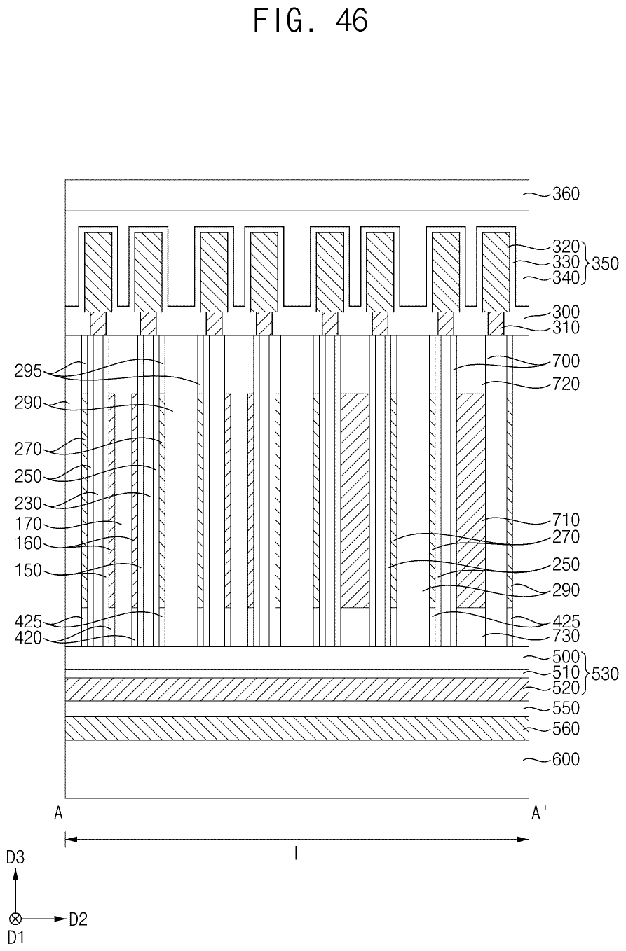

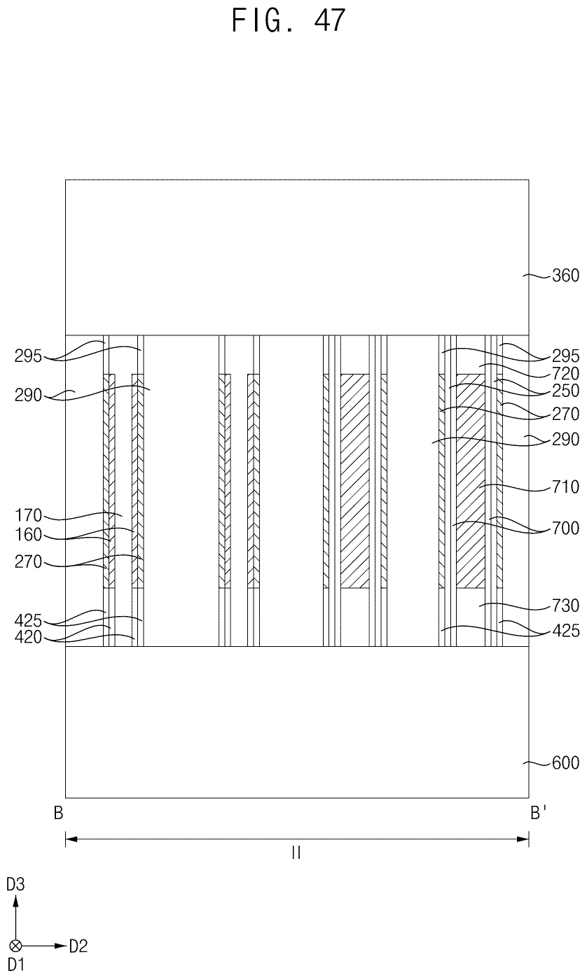

FIGS. 45 to 47 are a plan view and cross-sectional views illustrating a semiconductor device in accordance with example embodiments, which may correspond to FIGS. 1 to 3, respectively. The semiconductor device may be (substantially) the same as or similar to that of FIGS. 1 to 3, except for including a second extension structure instead of some of the first lower electrode structures, and thus repeated explanations may be omitted herein.

Referring to FIGS. 45 to 47, unlike the semiconductor device described with reference to FIGS. 1 to 3, the semiconductor device may include second extension structures (or a second extension structure) instead of some of the first extension structures.

In FIGS. 45 to 47, two second extension structures may be formed instead of two of the first extension structures on the right, but the concept of the present invention is not limited to the number or the arrangement of the first extension structures and the second extension structures. That is, for example, the two second extension structures may be formed instead of two of the first extension structures on the left, or, for example, the first and second extension structures may be formed alternately and repeatedly along the second direction D2.

The second extension structure may include a second sacrificial pattern 135, a third gate structure, a channel 230 sequentially formed on sidewalls of the third gate structure in the second direction D2, a second gate insulation pattern 250, and a second gate electrode 270.

Unlike the gate isolation pattern 210 including the bulk portion and the protruding structure, the second sacrificial pattern 135 may have a rectangular shape having a length in the first direction D1 being greater than a length in the second direction D2 in a plan view.

In example embodiments, the second sacrificial pattern 135 may include, for example, an oxide such as silicon oxide or a nitride such as silicon nitride.

The third gate structure may extend in the first direction D1 on the third insulating interlayer 600, the bit line structure 530, and the sixth insulation pattern 550, and the third gate structure may be one of a plurality of third gate structures spaced apart from each other in the second direction D2.

In example embodiments, the third gate structure may contact a sidewall in the first direction D1 of the second sacrificial pattern 135 adjacent to the first region I and extend in the first direction D1. However, a third gate insulation pattern 700 may be interposed between the third gate electrode 710 and the second sacrificial pattern 135. Accordingly, unlike the first gate electrode 160 that directly contacts the gate isolation pattern 210 in the first extension structure, the third gate electrode may not directly contact the second sacrificial pattern 135.

The third gate structure may include an eighth insulation pattern 730, a third gate electrode 710, and a seventh insulation pattern 720 sequentially stacked, and a third gate insulation pattern 700 on (e.g., covering or overlapping in the second direction D2) sidewalls of the eighth insulation pattern 730, the third gate electrode 710 and the seventh insulation pattern 720. Unlike the first gate electrode 160 and the second gate electrode 270 in the first extension structure, the third gate electrode 710 and the second gate electrode 270 in the second extension structure may not be in contact with each other. Thus, the second and third gate electrodes 270 and 710 may operate separately from each other.

In example embodiments, the third gate electrode 710 may include, for example, polysilicon doped with impurities. In example embodiments, the third gate electrode 710 may serve as a back gate electrode.

In example embodiments, the third gate insulation pattern 700 may include, for example, an oxide, such as silicon oxide, or a nitride, such as silicon nitride. In example embodiments, each of the seventh and eighth insulation patterns 720 and 730 may include, for example, an insulating nitride such as silicon nitride, an oxide such as silicon oxide, or air (e.g., gas or a space).

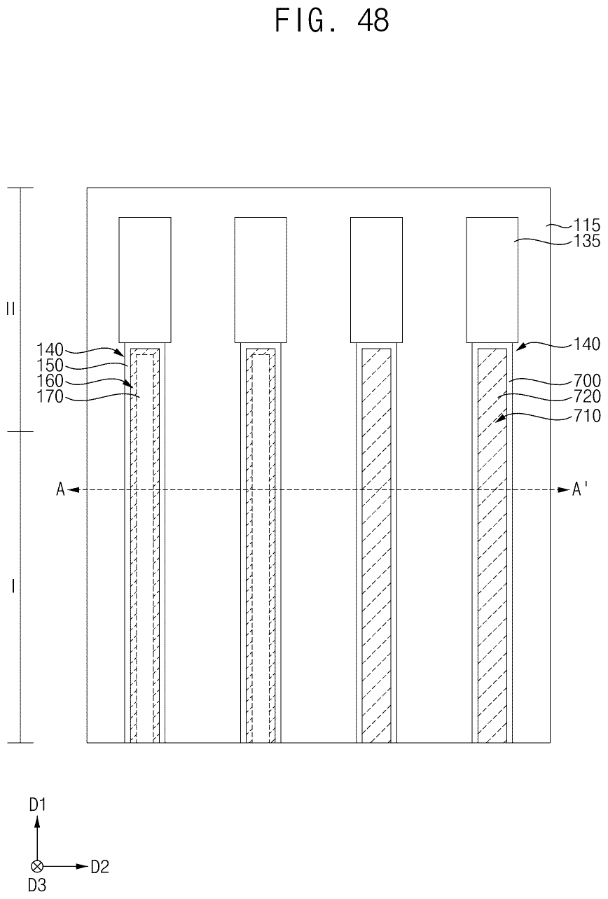

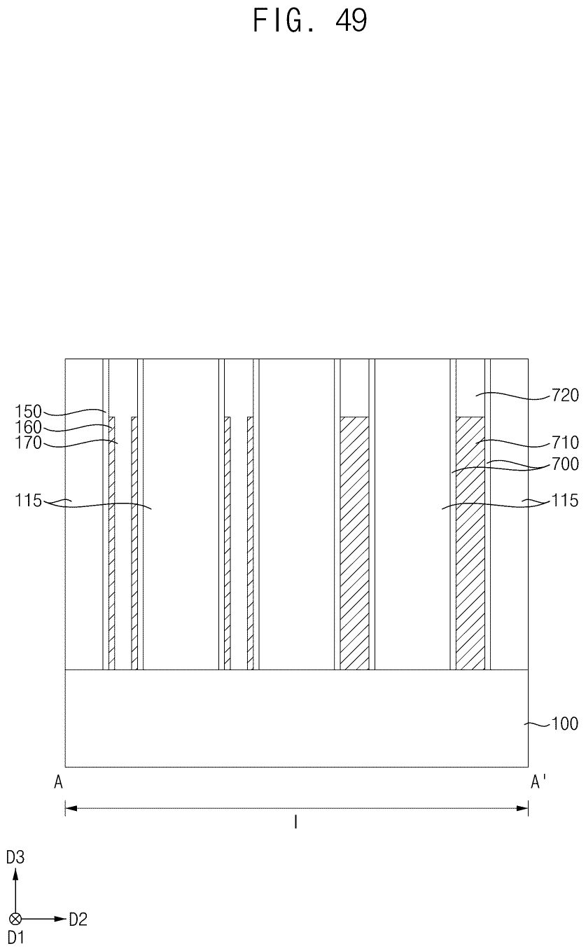

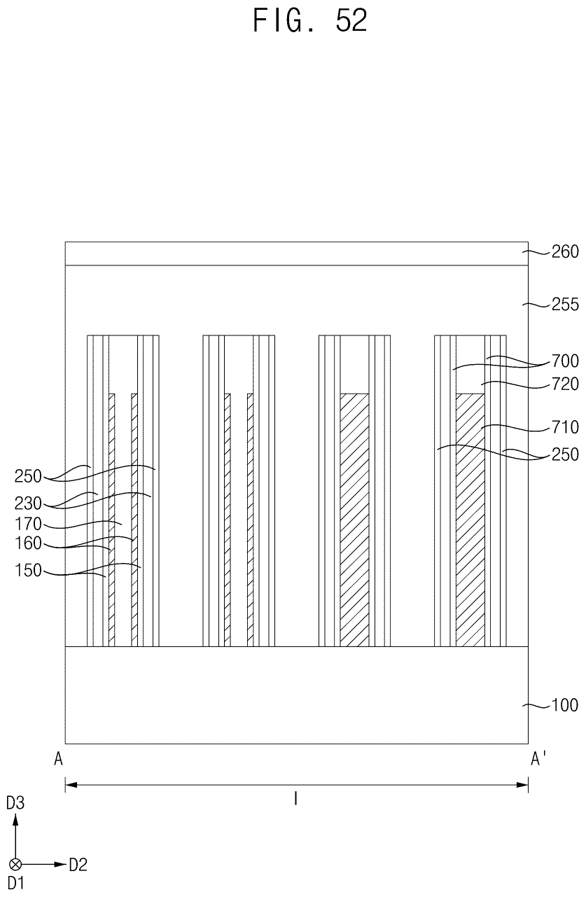

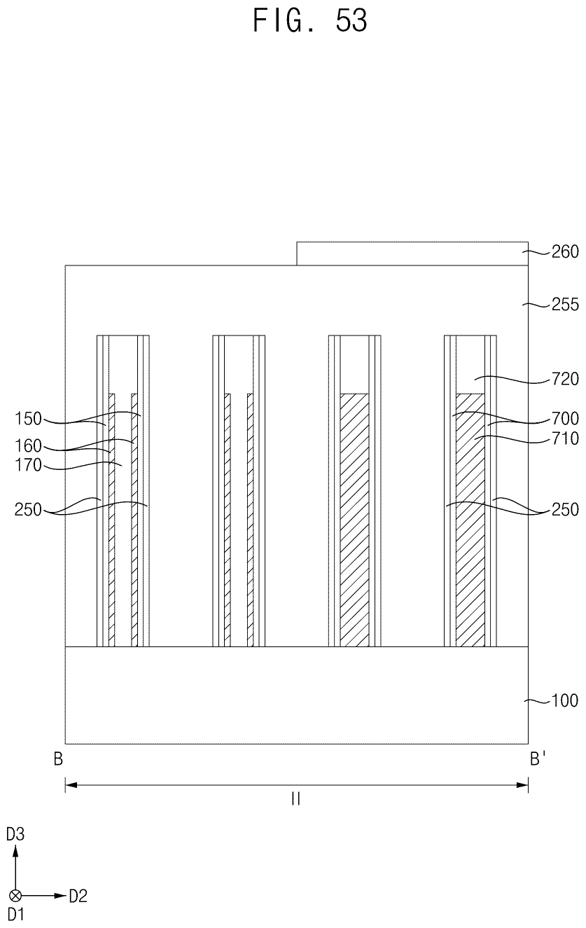

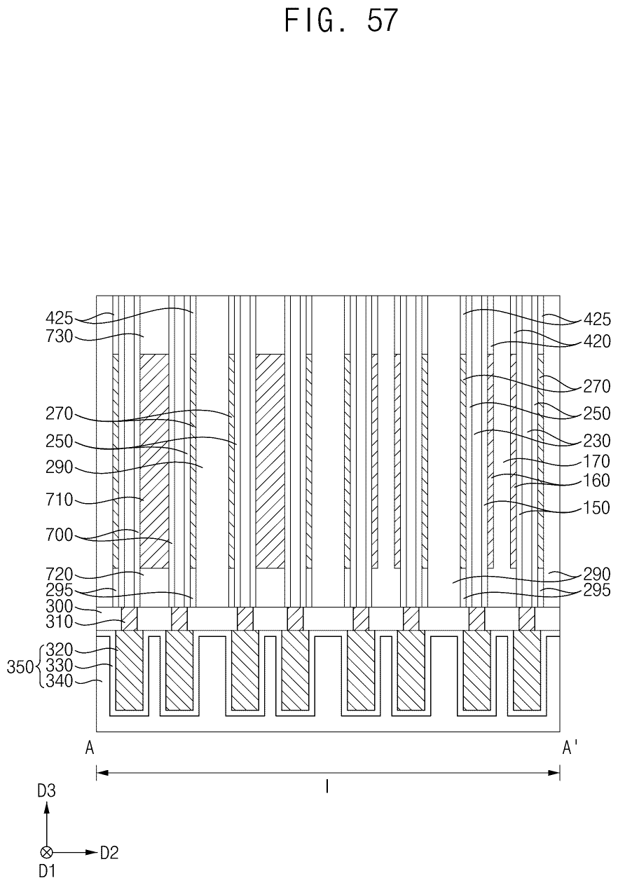

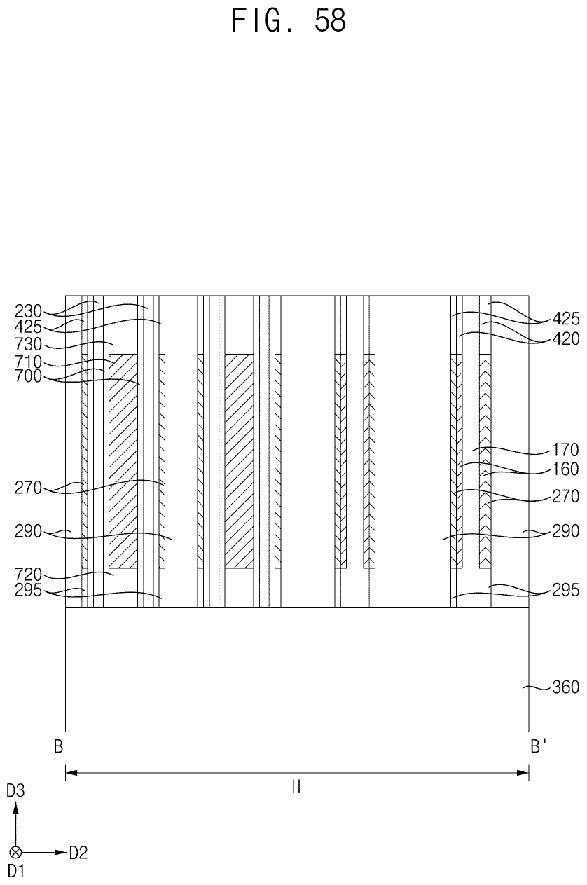

FIGS. 48 to 58 are plan views and cross-sectional views illustrating a method of forming a semiconductor device in accordance with example embodiments. Specifically, FIGS. 48, 50, 51, 54, and 56 are the plan views, FIGS. 49, 52, and 57 are cross-sectional views taken along lines A-A′, respectively, of corresponding plan views, and FIGS. 53, 55, and 58 are cross-sectional views taken along lines B-B′, respectively, of corresponding plan views. This method may include processes (substantially) the same as or similar to those illustrated with reference to FIGS. 1 to 44, and thus repeated explanations thereof may be omitted herein.

Referring to FIGS. 48 and 49, after performing processes (substantially) the same or similar to the processes described with reference to FIGS. 4 to 6, processes described with reference to FIGS. 7 and 8 may be performed. However, instead of the first gate insulation pattern 150, the first gate electrode 160, and the first insulation pattern 170, a third gate insulation pattern 700, a third gate electrode, 710 and a seventh insulation pattern 720 may be formed in at least one of the second openings 140.

The third gate insulation pattern 700 may be formed on the sidewall of the second opening 140, that is, the sidewall in the first direction D1 of the second sacrificial pattern 135 and the sidewall in the second direction D2 of the first sacrificial pattern 115. The third gate insulation pattern 700 may be formed by forming a third gate insulation layer on the bottom and the sidewalls of the second opening 140 and the upper surface of the first and second sacrificial patterns 115 and 135, and performing an anisotropic etching process on the third gate insulation layer.

The third gate electrode 710 may be formed to extend in the first direction D1 at a lower portion of the second opening 140. The third gate electrode 710 may be formed by forming a third gate electrode layer in the second opening 140 and then performing an etch back process on an upper portion of the third gate electrode layer.

The seventh insulation pattern 720 may be formed to fill a remaining portion of the second opening 140. Accordingly, the seventh insulation pattern 720 may extend in the first direction D1 on the third gate electrode 710. The seventh insulation pattern 720 may be formed by forming a seventh insulation layer in the second opening 140, and performing a planarization process on an upper portion of the seventh insulation layer until the upper surfaces the first and second sacrificial patterns 115 and 135 is exposed.

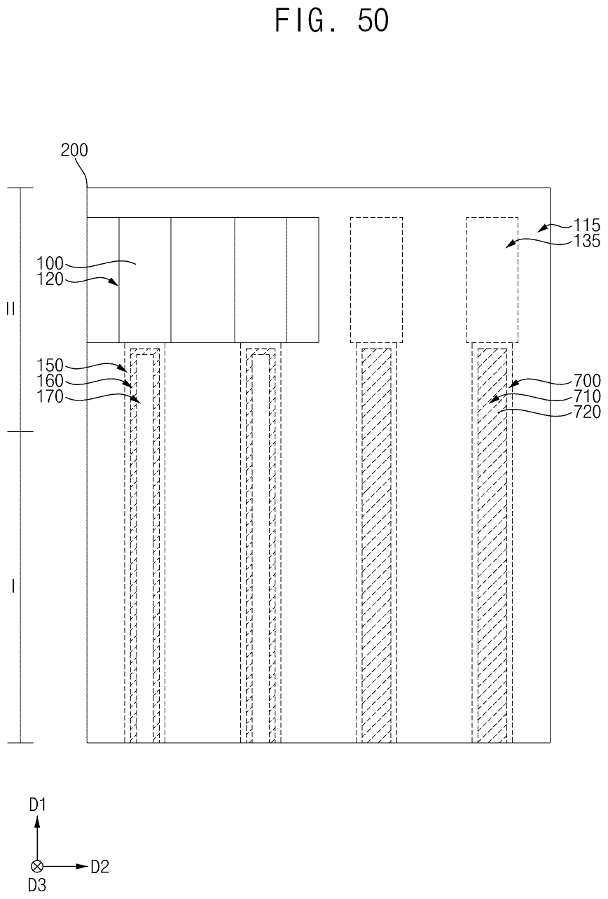

Referring to FIG. 50, processes described with reference to FIG. 9 may be performed. However, the third opening included in the first mask 200 may not overlap in the third direction D3 with the at least one of the second sacrificial patterns 135. Specifically, the third opening may not overlap in the third direction D3 with the at least one of the second sacrificial patterns 135 in contact with the third gate insulation pattern 700, and accordingly, the second sacrificial pattern 135 may not be removed during the etching process using the first mask 200.

Hereinafter, the third gate insulation pattern 700, the third gate electrode 710 and the seventh insulation pattern 720, and the channel 230, and second gate insulation pattern 250 formed afterwards may together be referred to as the preliminary second extension structure.

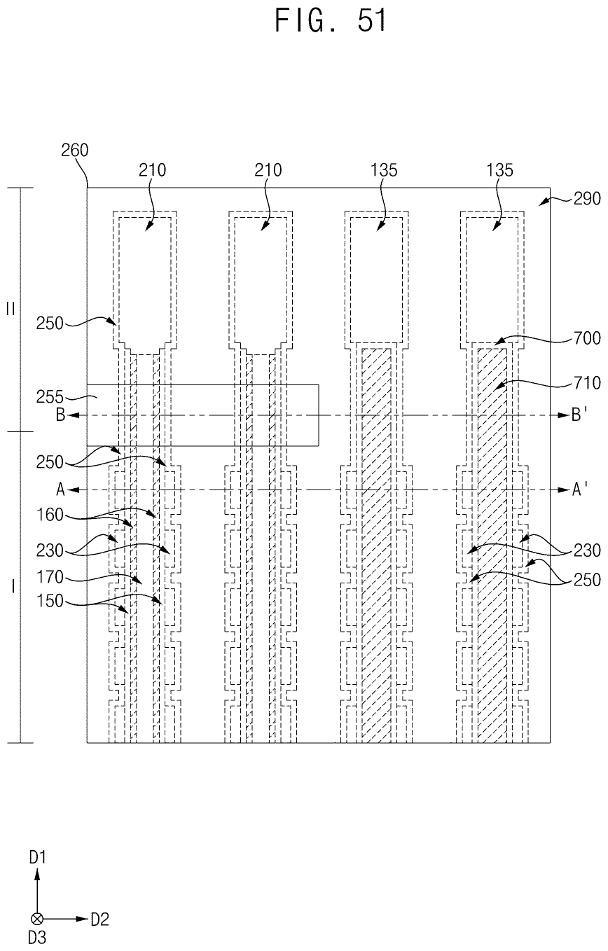

Referring to FIGS. 51 to 53, processes (substantially) the same or similar to processes described with reference to FIGS. 10 to 20 may be performed, and processes described with reference to FIGS. 21 and 22 may be performed. However, the fifth opening included in the third mask 260 may not overlap the preliminary second extension structure in the third direction D3.

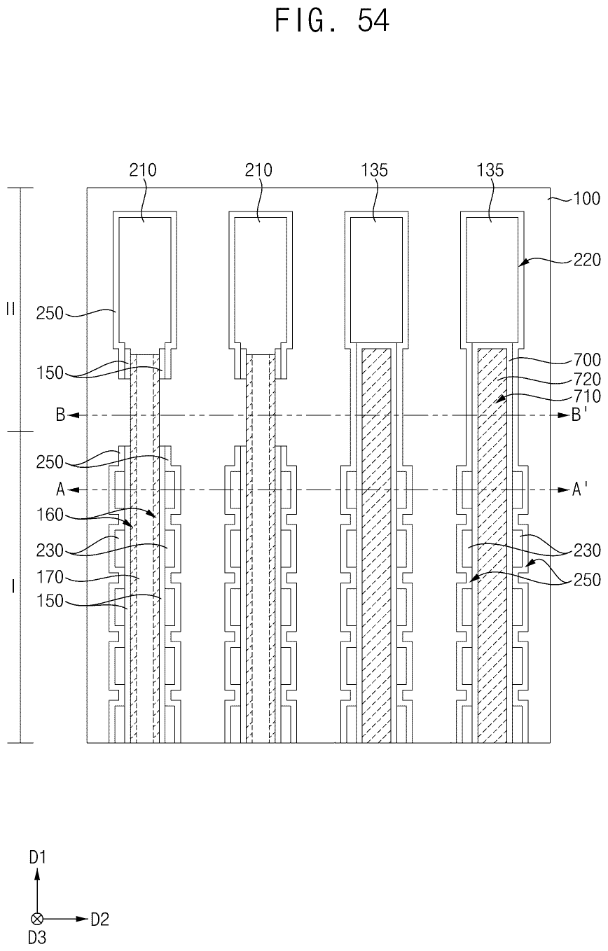

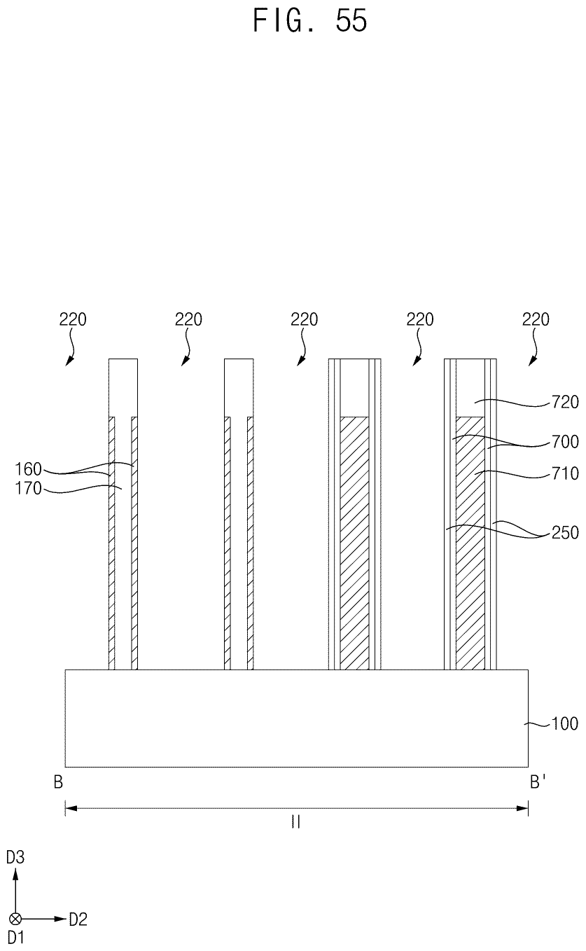

Referring to FIGS. 54 and 55, processes described with reference to FIGS. 23 and 24 may be performed. However, the fifth opening may not overlap the preliminary second extension structure in the third direction D3. Thus, the second and third gate insulation patterns 250 and 700 included in the preliminary second extension structure may not be removed during the etching process using the third mask 260.

Accordingly, a sidewall of the third gate electrode 710 may not be exposed. Thus, even if the second gate electrode 270 is formed along a sidewall of the preliminary second extension structure, the second gate electrode 270 and the third gate electrode 710 may not contact each other.

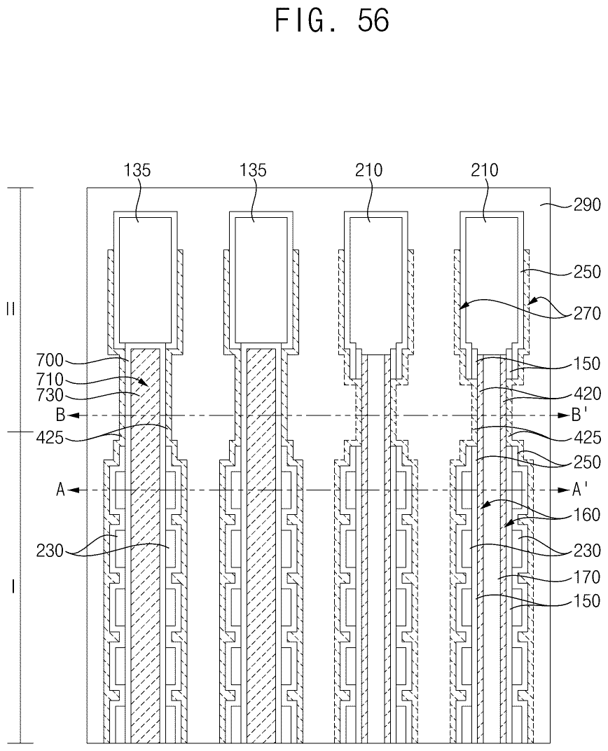

Referring to FIGS. 56 to 58, processes described with reference to FIGS. 25 to 37 may be performed, and afterwards, processes described with reference to FIGS. 38 to 40 may be performed. However, a fifth recess may be additionally formed by partially removing an upper portion of the third gate electrode 710, and an eighth insulation pattern 730 may be formed within the fifth recess.

The eighth insulation pattern 730 may be formed to extend in the first direction D1 on the third gate electrode 710. The seventh insulation pattern 720, the third gate electrode 710 and the eighth insulation pattern 730, and the third gate insulation pattern 700 on (e.g., covering or overlapping in the second direction D2) sidewalls thereof may together form a third gate structure.

Processes (substantially) the same as or similar to those illustrated with reference to FIGS. 41 to 44 and FIGS. 1 to 3 may be performed to complete the fabrication of the semiconductor device.

While example embodiments have been particularly shown and described, it will be understood by one of ordinary skill in the art that variations in form and detail may be made therein without departing from the scope of the claims.

What is claimed is:

1. A semiconductor device, comprising:
a substrate;
bit line structures on the substrate, wherein the bit line structures are spaced apart from each other in a first direction that is parallel with an upper surface of the substrate, and each of the bit line structures extends in a second direction that is parallel with the upper surface of the substrate and intersects the first direction;
channels on the bit line structures, wherein the channels are electrically connected to the bit line structures and spaced apart from each other in the first direction;
a gate insulation pattern structure on sidewalls of each of the channels;
a gate electrode structure including:
a first gate electrode on a first sidewall in the second direction of the gate insulation pattern structure; and
a second gate electrode on a second sidewall in the second direction of the gate insulation pattern structure,
wherein the second sidewall of the gate insulation pattern structure faces the first sidewall of the gate insulation pattern structure in the second direction,
wherein the second gate electrode is on a third sidewall in the first direction of an end portion in the first direction of the gate insulation pattern structure, and
wherein the second gate electrode is in contact with the first gate electrode; and
capacitors on the channels, wherein the capacitors are electrically connected to the channels, respectively.

2. The semiconductor device according to claim 1, wherein the gate insulation pattern structure includes:
a first gate insulation pattern that is in contact with a first sidewall in the second direction of each of the channels; and
a second gate insulation pattern that is in contact with a second sidewall in the second direction of each of the channels and in contact with third and fourth sidewalls in the first direction of each of the channels,
wherein the second sidewall of each of the channels faces the first sidewall of each of the channels in the second direction, respectively, and
wherein the fourth sidewall of each of the channels faces the third sidewall of each of the channels in the first direction, respectively.

3. The semiconductor device according to claim 2, wherein the first gate insulation pattern includes a first material and has a first thickness in a plan view,
wherein the second gate insulation pattern includes a second material and has a second thickness in the plan view, and
wherein the first material is different from the second material, and/or the first thickness is different from the second thickness.

4. The semiconductor device according to claim 3, wherein each of the first material and the second material includes an oxide, a nitride, and/or air.

5. The semiconductor device according to claim 1, wherein the first gate electrode includes a first material and has a first thickness in a plan view,
wherein the second gate electrode includes a second material and has a second thickness in the plan view, and
wherein the first material is different from the second material, and/or the first thickness is different from the second thickness.

6. The semiconductor device according to claim 1, wherein an upper surface of the gate electrode structure is closer than an upper surface of the gate insulation pattern structure to the upper surface of the substrate, and
wherein a lower surface of the gate electrode structure is farther than a lower surface of the gate insulation pattern structure from the upper surface of the substrate.

7. The semiconductor device according to claim 1, further comprising:
a gate isolation pattern on the bit line structures,
wherein the gate isolation pattern is in contact with an end portion in the first direction of the first gate electrode.

8. The semiconductor device according to claim 7, wherein the second gate electrode overlaps in the second direction with the gate isolation pattern.

9. The semiconductor device according to claim 1, further comprising:
a contact plug that is in contact with the second gate electrode.

10. A semiconductor device, comprising:
a substrate;
bit line structures on the substrate, wherein the bit line structures are spaced apart from each other in a first direction that is parallel with an upper surface of the substrate, and each of the bit line structures extends in a second direction that is parallel with the upper surface of the substrate and intersects the first direction;
an insulation pattern structure on the bit line structures, wherein the insulation pattern structure extends in the first direction;
a gate isolation pattern that is in contact with an end portion in the first direction of the insulation pattern structure;
channels on the bit line structures, wherein the channels are electrically connected to the bit line structures and spaced apart from each other in the first direction on opposite sidewalls in the second direction of the insulation pattern structure;
a gate insulation pattern structure on the bit line structures, wherein the gate insulation pattern structure is on the opposite sidewalls in the second direction of the insulation pattern structure and sidewalls of the channels;
a gate electrode structure on the bit line structures, wherein the gate electrode structure is on the opposite sidewalls in the second direction of the insulation pattern structure,
wherein the gate electrode structure at least partially extends around the gate insulation pattern structure, and
wherein the gate electrode structure overlaps in the second direction with the gate isolation pattern; and
capacitors on the channels, wherein the capacitors are electrically connected to the channels, respectively.

11. The semiconductor device according to claim 10, wherein the gate electrode structure is on opposite sidewalls in the second direction of the gate insulation pattern structure and a sidewall in the first direction of an end portion in the first direction of the gate insulation pattern structure.

12. The semiconductor device according to claim 10, wherein the gate electrode structure includes:
a first gate electrode on a first sidewall in the second direction of the gate insulation pattern structure; and
a second gate electrode on a second sidewall in the second direction of the gate insulation pattern structure,
wherein the second sidewall of the gate insulation pattern structure faces the first sidewall of the gate insulation pattern structure in the second direction, and
wherein the second gate electrode is on a third sidewall in the first direction of an end portion in the first direction of the gate insulation pattern structure.

13. The semiconductor device according to claim 12, wherein the second gate electrode overlaps in the second direction with the gate isolation pattern.

14. The semiconductor device according to claim 10, wherein the gate insulation pattern structure includes:
a first gate insulation pattern on a first sidewall in the second direction among the sidewalls of each of the channels; and
a second gate insulation pattern that is in contact with a second sidewall in the second direction among the sidewalls of each of the channels and in contact with third and fourth sidewalls in the first direction among the sidewalls of each of the channels,
wherein the second sidewall of each of the channels faces the first sidewall of each of the channels in the second direction, respectively, and
wherein the fourth sidewall of each of the channels faces the third sidewall of each of the channels in the first direction, respectively.

15. The semiconductor device according to claim 14, wherein the second gate insulation pattern is in contact with a sidewall of the first gate insulation pattern between adjacent channels in the first direction among the channels.

16. A semiconductor device, comprising:
a substrate;
bit line structures on the substrate, wherein the bit line structures are spaced apart from each other in a first direction that is parallel with an upper surface of the substrate, and each of the bit line structures extends in a second direction that is parallel with the upper surface of the substrate and intersects the first direction;
an insulation pattern structure on the bit line structures, wherein the insulation pattern structure extends in the first direction;
channels on the bit line structures, wherein the channels are electrically connected to the bit line structures and spaced apart from each other in the first direction on opposite sidewalls in the second direction of the insulation pattern structure;
a gate isolation pattern that is in contact with an end portion in the first direction of the insulation pattern structure;
a gate insulation pattern structure on sidewalls of each of the channels;
a gate electrode structure including:
a first gate electrode on a first sidewall in the second direction of the gate insulation pattern structure; and
a second gate electrode on a second sidewall in the second direction of the gate insulation pattern structure,
wherein the second sidewall of the gate insulation pattern structure faces the first sidewall of the gate insulation pattern structure in the second direction,
wherein the second gate electrode is on a third sidewall in the first direction of an end portion in the first direction of the gate insulation pattern structure, and
wherein the second gate electrode is in contact with the first gate electrode;
capacitors on the channels, wherein the capacitors are electrically connected to the channels; and
contact plug that is in contact with the second gate electrode.

17. The semiconductor device according to claim 16, wherein the first gate electrode contacts the opposite sidewalls in the second direction of the insulation pattern structure.

18. The semiconductor device according to claim 16, wherein the second gate electrode overlaps in the second direction with the gate isolation pattern.

19. The semiconductor device according to claim 16, wherein the gate insulation pattern structure includes:
a first gate insulation pattern on a first sidewall in the second direction among the sidewalls of each of the channels; and
a second gate insulation pattern that is in contact with a second sidewall in the second direction among the sidewalls of each of the channels and third and fourth sidewalls in the first direction among the sidewalls of each of the channels,
wherein the second sidewall of each of the channels faces the first sidewall of each of the channels in the second direction, respectively, and
wherein the fourth sidewall of each of the channels faces the third sidewall of each of the channels in the first direction, respectively.

20. The semiconductor device according to claim 16, wherein the second gate electrode includes:
an extension portion that extends in the first direction; and
a protruding portion that protrudes from the extension portion in the second direction.
